(19) United States
(12) Patent Application Publication
(10) Pub. No.: US 2025/0210605 A1
(43) Pub. Date: Jun. 26, 2025

(54) Stretchable Display Device and Method of Manufacturing the Same

(71) Applicant: LG Display Co., Ltd., Seoul (KR)

(72) Inventors: Yu-Ra Jeong, Paju-si (KR); Sung-Joon Min, Paju-si (KR); Hae-Yoon Jung, Paju-si (KR); Ji-Ho Kang, Paju-si (KR); Myung-Sub Lim, Paju-si (KR); In-Jun Lee, Paju-si (KR)

(21) Appl. No.: 18/954,115

(22) Filed: Nov. 20, 2024

(30) Foreign Application Priority Data
Dec. 22, 2023 (KR) 10-2023-0189649

(51) Int. Cl. H01L 25/16; H01L 25/075; H01L 33/54; H01L 33/62

(52) U.S. Cl. CPC H01L 25/167; H01L 25/0753; H10H 20/853; H10H 20/857; H10H 20/0362

(57) ABSTRACT

A stretchable display device includes a first substrate provided with a rigid portion and a soft portion; a thin film transistor in the rigid portion on the first substrate; a planarization layer on the thin film transistor; a stretchable line in the soft portion on the first substrate; an encapsulation layer on the stretchable line; a light-emitting element on the planarization layer and electrically connected to the thin film transistor; and a second substrate spaced apart from the first substrate, wherein a distance between the first substrate and a top surface of the encapsulation layer is greater than a distance between the first substrate and a top surface of the planarization layer.

### CROSS-REFERENCE TO RELATED APPLICATION

The present application claims priority to Republic of Korea Patent Application No. 10-2023-0189649 filed on Dec. 22, 2023, which is hereby incorporated by reference in its entirety.

### BACKGROUND

### Field of the Disclosure

The present disclosure relates to a display device, and more particularly, to a stretchable display device and a method of manufacturing the same.

### Discussion of the Background Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

### SUMMARY

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid portion in which a pixel is disposed and a soft portion in which a connection line connecting the pixels is disposed. The rigid portion may not be stretched, and the soft portion may be stretched.

At this time, in order to secure stretching properties, the thickness of the soft portion may be smaller than the thickness of the rigid portion. Accordingly, there may be a step difference between the rigid portion and the soft portion. The structure of the applicable light-emitting element may be limited due to the step difference, and defects may occur when transferring the light-emitting elements.

Accordingly, the present disclosure is to provide a stretchable display device that substantially obviates one or more of the limitations and disadvantages described above and associated with the background art.

More specifically, an object of the present disclosure is to provide a stretchable display device capable of applying light-emitting elements of various structures and a method of manufacturing the same.

Another object of the present disclosure is to provide a stretchable display device capable of preventing defects during transfer of light-emitting elements and a method of manufacturing the same.

Additional features and embodiments will be set forth in the description that follows, and in part will be apparent from the description, or can be learned by practice of the present disclosure provided herein. Other features and embodiments of the inventive concepts can be realized and attained by the structure particularly pointed out in the written description, or derivable therefrom, as well as the appended drawings.

To achieve these and other embodiments of the present disclosure, as embodied and broadly described herein, a stretchable display device includes a first substrate provided with a rigid portion and a soft portion; a thin film transistor in the rigid portion on the first substrate; a planarization layer on the thin film transistor; a stretchable line in the soft portion on the first substrate; an encapsulation layer on the stretchable line; a light-emitting element on the planarization layer and electrically connected to the thin film transistor; and a second substrate spaced apart from the first substrate, wherein a distance between the first substrate and a top surface of the encapsulation layer is greater than a distance between the first substrate and a top surface of the planarization layer.

In another embodiment, a method of manufacturing a stretchable display device includes forming a thin film transistor in a rigid portion on a substrate provided with the rigid portion and a soft portion; forming a stretchable line in the soft portion on the substrate; forming a planarization layer on the thin film transistor; transferring a light-emitting element on the planarization layer and electrically connected to the thin film transistor; and forming an encapsulation layer on the stretchable line, wherein a distance between the substrate and a top surface of the encapsulation layer is greater than a distance between the substrate and a top surface of the planarization layer.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic perspective view of a stretchable display device according to an embodiment of the present disclosure;

FIG. 2 is a plan view schematically illustrating a part of a stretchable display device according to the embodiment of the present disclosure;

FIG. 3 is an equivalent circuit diagram for a sub-pixel of a stretchable display device according to the embodiment of the present disclosure;

FIG. 4 is a cross-sectional views of a stretchable display device corresponding to line I-I′ of FIG. 2 according to a first embodiment of the present disclosure;

FIG. 5 is a cross-sectional view of a stretchable display device corresponding to line II-II′ of FIG. 2 according to the first embodiment of the present disclosure;

FIGS. 6A to 6M are schematic cross-sectional views of a stretchable display device corresponding to line I-I′ of FIG. 2 in steps of manufacturing the same according to the first embodiment of the present disclosure;

FIGS. 7A to 7H are schematic cross-sectional views of a stretchable display device corresponding to line II-II′ of FIG. 2 in steps of manufacturing the same according to the first embodiment of the present disclosure;

FIG. 8 is a cross-sectional view corresponding to one sub-pixel of a stretchable display device corresponding to line I-I′ of FIG. 2 according to a second embodiment of the present disclosure;

FIG. 9 is a cross-sectional view corresponding to one sub-pixel of a stretchable display device corresponding to line II-II′ of FIG. 2 according to the second embodiment of the present disclosure;

FIGS. 10A to 10G are schematic cross-sectional views of a stretchable display device corresponding to line I-I′ of FIG. 2 in steps of manufacturing the same according to the second embodiment of the present disclosure; and

FIGS. 11A to 11F are schematic cross-sectional views of a stretchable display device corresponding to line II-II′ of FIG. 2 in steps of manufacturing the same according to the second embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

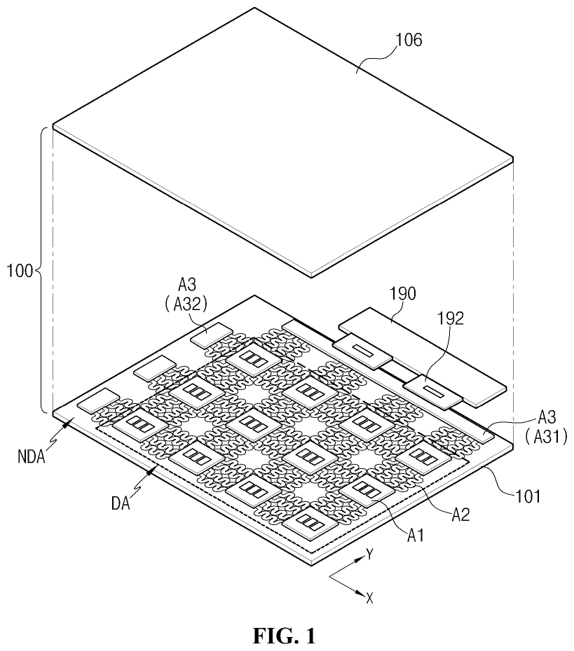

FIG. 1 is a schematic perspective view of a stretchable display device according to an embodiment of the present disclosure.

In FIG. 1, a stretchable display device according to an embodiment of the present disclosure may include a display panel 100, a printed circuit board 190, and a flexible printed circuit 192.

The display panel 100 may be stretched in a first direction X and/or a second direction Y. The display panel 100 may include a first substrate 101 and a second substrate 106, and a display area DA displaying an image and a non-display area NDA provided on and surrounding at least one side of the display area DA may be defined on the first substrate 101.

A rigid portion A1 corresponding to a first area and a soft portion A2 (which may also be referred to herein as a flexible portion A2) corresponding to a second area may be provided in the display area DA of the first substrate 101, and a pad portion A3 corresponding to a third area may be provided in the non-display area NDA of the first substrate 101.

The rigid portion A1 may be provided in the form of an island, and a plurality of rigid portions A1 may be disposed to be spaced apart from each other along the first direction X and the second direction Y. The rigid portions A1 may be arranged in a matrix form. For example, the rigid portion A1 may have a substantially tetragonal or polygonal shape.

A pixel including a plurality of sub-pixels may be provided in the rigid portion A1. Each of the plurality of sub-pixels may include a light-emitting diode, at least one thin film transistor, a plurality of lines, and a plurality of electrodes.

The soft portion A2 may be disposed between the rigid portions A1 adjacent to each other in each of the first direction X and the second direction Y. Multiple soft portions A2 may be provided between the adjacent rigid portions A1. In addition, the soft portion A2 may be disposed between the rigid portion A1 and the pad portion A3 (e.g., first pad portion A31) adjacent to each other in the second direction Y and between the rigid portion A1 and the pad portion A3 (e.g., second pad portion A32) adjacent to each other in the first direction X.

A stretchable line that is a connection line connecting the adjacent pixels may be provided in the soft portion A2. The stretchable line may include a plurality of voltage lines such as a gate line, a data line, a high potential line, a low potential line, an emission line, and a reference voltage line.

The stretchable line may have at least one curved shape. For example, the stretchable line may have a wave structure.

Meanwhile, the non-display area NDA may be an area in which an image is not displayed, and the pad portion A3 may be disposed in the non-display area NDA. A plurality of link lines extending from the plurality of voltage lines disposed in the display area DA and a plurality of pads connected to ends of the plurality of link lines may be provided in the pad portion A3.

The pad portion A3 may include a first pad portion A31 and a second pad portion A32. The first pad portion A31 may correspond to the rigid portions A1 arranged in the first direction X, and the second pad portion A32 may correspond to the rigid portions A1 arranged in the second direction Y. The first pad portion A31 may be disposed on at least one of upper and lower sides of the display area DA, and the second pad portion A32 may be disposed on at least one of left and right sides of the display area DA. For example, as shown in FIG. 1, the first pad portion A31 may be disposed on the upper side of the display area DA, and the second pad portion A32 may be disposed on the left side of the display area DA.

The first pad portion A31 may be provided as one pattern corresponding to the plurality of rigid portions A1 arranged in the first direction X. That is, the first pad portion A31 configured as one rigid pattern may correspond to the plurality of rigid portions A1.

On the other hand, the second pad portion A32 may be separated to correspond to each of the plurality of rigid portions A1 arranged in the second direction Y. That is, the second pad portions A32 configured as a plurality of rigid patterns may correspond to the plurality of rigid portions A1, respectively.

However, embodiments of the present disclosure are not limited thereto. In other embodiments, the first pad portion A31 may be separated to correspond to each of the plurality of rigid portions A1 arranged in the first direction X, and the second pad portion A32 may be provided as one pattern corresponding to the plurality of rigid portions A1 arranged in the second direction Y.

The rigid portion A1 and the pad portion A3 may not be stretched, and the soft portion A2 may be stretched.

Meanwhile, the flexible printed circuit 192 may be connected to the first pad portion A31 of the pad portion A3. The flexible printed circuit 192 may include a base film made of a flexible material and a driver integrated circuit chip (driver IC chip) mounted on the base film. The flexible printed circuit 192 may generate a gate signal and a data signal for displaying the image and transmit the gate signal and the data signal to the display panel 100.

In the embodiment of FIG. 1, the flexible printed circuit 192 is shown to be a chip on film (COF) type, but embodiments of the present disclosure are not limited thereto. In other embodiments, the flexible printed circuit 192 may be a chip on glass (COG) type or a tape carrier package (TCP) type.

The printed circuit board 190 may include a circuit part for controlling the driver IC chip. For example, the printed circuit board 190 may include a timing controller receiving an image signal and a plurality of timing signals, generating a plurality of control signals, and transmitting the generated control signals to the driver IC chip.

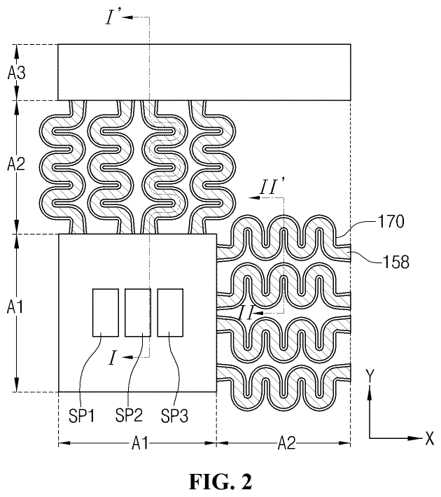

FIG. 2 is a plan view schematically illustrating a part of a stretchable display device according to the embodiment of the present disclosure.

In FIG. 2, the stretchable display device according to the embodiment of the present disclosure may include the rigid portion A1 and the soft portion A2 and the pad portion A3.

In the rigid portion A1, the plurality of sub-pixels SP1, SP2, and SP3 may be provided on a substrate of a rigid material. For example, first, second, and third sub-pixels SP1, SP2, and SP3 may be provided in the rigid portion A1, and the first, second, and third sub-pixels SP1, SP2, and SP3 may be red, green, and blue sub-pixels.

Each of the first, second, and third sub-pixels SP1, SP2, and SP3 may include a light-emitting element, at least one transistor, and at least one capacitor.

In the soft portion A2, a stretchable or flexible line 158 and an encapsulation layer 170 may be provided. The encapsulation layer 170 may be disposed on the stretchable line 158, and the width of the encapsulation layer 170 may be equal to or wider than the width of the stretchable line 158.

The stretchable line 158 and the encapsulation layer 170 may have the same shape and may include at least one curved part. For example, the stretchable line 158 and the encapsulation layer 170 may have a wave structure and may include a plurality of wave shapes of repeated crests and troughs. In an embodiment, the wavelength (i.e., distance between successive crests or successive troughs) is equidistant across the stretchable line 158 or may be different or may vary along the stretchable line 158.

Four stretchable lines 158 may be disposed between the adjacent or successive rigid portions A1 or between the rigid portion A1 and the pad portion A3 adjacent to each other. Two stretchable lines 158 may be disposed symmetrically with other two stretchable lines 158.

However, embodiments of the present disclosure are not limited thereto. The stretchable line 158 may have various structures. For example, in other embodiments, the stretchable line 158 may have an omega structure in which two omega shapes are connected to each other, among other possibilities.

In pad portion A3, the plurality of link lines connected to the plurality of stretchable lines 158 and the plurality of pads connected to the ends of the plurality of link lines may be provided.

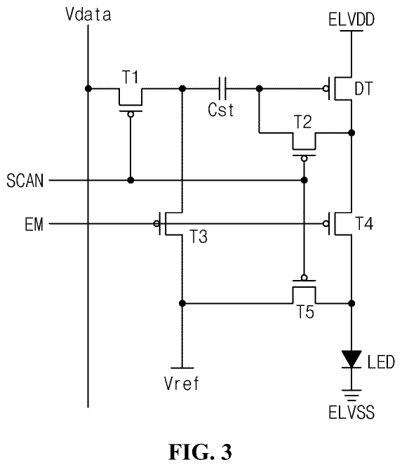

FIG. 3 is an equivalent circuit diagram for a sub-pixel of a stretchable display device according to the embodiment of the present disclosure.

In FIG. 3, one sub-pixel of the stretchable display device according to the embodiment of the present disclosure, that is, each of the first, second, and third sub-pixels SP1, SP2, and SP3 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the gate signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the gate signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 3, as an example, each sub-pixel has a 6T1C structure including six transistors and one capacitor, but in other embodiments, each sub-pixel may have one of 2T1C, 4T1C, 5T1C, 3T2C, 4T2C, 5T2C, 6T2C, 7T1C, 7T2C, 8T1C, and 8T2C structures.

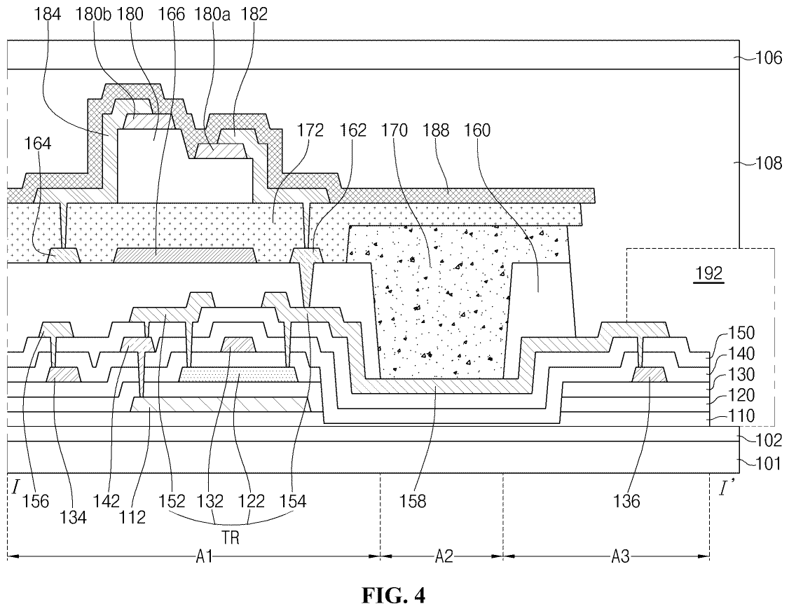

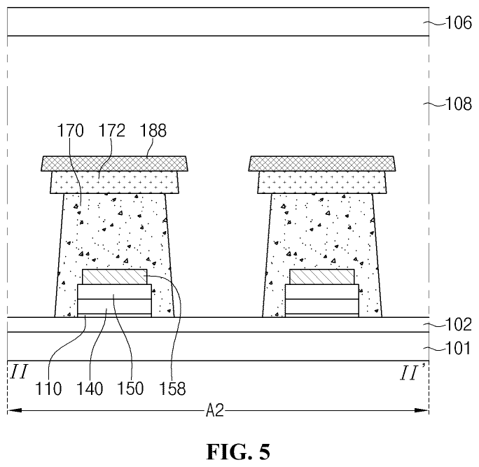

A cross-sectional structure of one or more embodiments of the stretchable display device of the present disclosure will be described in detail with reference to FIG. 4 and FIG. 5.

FIG. 4 and FIG. 5 are cross-sectional views corresponding to one sub-pixel of a stretchable display device according to a first embodiment of the present disclosure. FIG. 4 shows a cross-section corresponding to line I-I′ of FIG. 2, and FIG. 5 shows a cross-section corresponding to line II-II′ of FIG. 2. FIG. 4 and FIG. 5 will be described with reference to FIGS. 1 to 3 together.

In FIG. 4 and FIG. 5, the stretchable display device according to the first embodiment of the present disclosure may include the first substrate 101 and the second substrate 106 facing and spaced apart from each other.

The first substrate 101 and the second substrate 106, which are flexible substrates, may be formed of a soft matter or soft material with bending or stretching properties. For example, the first substrate 101 and the second substrate 106 may be formed of silicone rubber such as polydimethylsiloxane (PDMS), elastomer such as polyurethane (PU), or styrene butadiene block copolymer such as styrene butadiene styrene (SBS).

The first substrate 101 and the second substrate 106 may be formed of the same material. However, embodiments of the present disclosure are not limited thereto. In other embodiments, the first substrate 101 and the second substrate 106 may be formed of different materials.

The first substrate 101 and the second substrate 106 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked.

For example, each of the first substrate 101 and the second substrate 106 may have the elastic modulus of several MPa to hundreds of MPa and the ductile breaking rate of about 100% or more. In addition, each of the first substrate 101 and the second substrate 106 may have a thickness of about 10 μm to about 1 mm. However, embodiments of the present disclosure are not limited thereto.

The rigid portion A1 corresponding to the first area, the soft portion A2 corresponding to the second area, and the pad portion A3 corresponding to the third area may be provided on the first substrate 101 and the second substrate 106.

A first adhesive layer 102 may be provided on the first substrate 101. The first adhesive layer 102 may be formed of an acryl-based, silicon-based, or urethane-based adhesive. For example, the first adhesive layer 102 may be optically clear adhesive (OCA) that is formed and attached in the form of a film or optically clear resin (OCR) that is cured after applying a liquid material.

Meanwhile, in other embodiments, the first adhesive layer 102 may be included in an inner surface of the first substrate 101, or the first adhesive layer 102 may be omitted.

A first buffer layer 110 may be provided on the first substrate 101 and the first adhesive layer 102 as a first insulation layer. The first buffer layer 110 may block permeation of moisture or oxygen from the outside to protect the components of the plurality of sub-pixels SP1, SP2, and SP3.

The first buffer layer 110 may be formed as a single layer or multiple layers of an inorganic insulating material. The inorganic insulating material of the first buffer layer 110 may include silicon nitride (SiNₓ), silicon oxide (SiOₓ), or silicon oxynitride (SiON).

In order to prevent or reduce damage of the first buffer layer 110 such as cracks due to stretching, the first buffer layer 110 may be removed in the soft portion A2 to substantially correspond to the rigid portion A1 and the pad portion A3. In this case, to control the thickness and hardness of the soft portion A2, the first buffer layer 110 may be partially provided with a relatively thin thickness over the first adhesive layer 102 in the soft portion A2. That is, the first buffer layer 110 may be completely removed or partially removed in the soft portion A2. Accordingly, the thickness of the first buffer layer 110 in the rigid portion A1 and the pad portion A3 may be greater than the thickness of the first buffer layer 110 in the soft portion A2.

Meanwhile, in other embodiments, the first buffer layer 110 may be omitted.

A light blocking layer 112 may be provided on the first buffer layer 110 of the rigid portion A1. The light blocking layer 112 may be formed of a conductive material such as metal. For example, the light blocking layer 112 may be formed of at least one of aluminum (Al), copper (Cu), molybdenum (Mo), titanium (Ti), chromium (Cr), nickel (Ni), tungsten (W), or an alloy thereof. The light blocking layer 112 may have a single-layered structure or a multiple-layered structure.

A second buffer layer 120 may be provided on the light blocking layer 112 of the rigid portion A1 as a second insulation layer. The second buffer layer 120 may be formed as a single layer or multiple layers of an inorganic insulating material. The inorganic insulating material of the second buffer layer 120 may include silicon nitride (SiNₓ), silicon oxide (SiOₓ), or silicon oxynitride (SiON).

In addition, the second buffer layer 120 may be provided on the first buffer layer 110 of the pad portion A3 and may not be provided in the soft portion A2.

A semiconductor layer 122 may be provided on the second buffer layer 120 of the rigid portion A1. The semiconductor layer 122 may overlap the light blocking layer 112, and the light blocking layer 112 may block light incident on the semiconductor layer 122 and prevent or reduce the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 130 may be provided on the semiconductor layer 122 of the rigid portion A1 as a third insulation layer. The gate insulation layer 130 may be formed as a single layer or multiple layers of an inorganic insulating material. The inorganic insulating material of the gate insulation layer 130 may include silicon nitride (SiNₓ), silicon oxide (SiOₓ), or silicon oxynitride (SiON).

In addition, the gate insulation layer 130 may be provided on the second buffer layer 120 of the pad portion A3 and may not be provided in the soft portion A2.

A gate electrode 132 and a signal pad 134 may be provided on the gate insulation layer 130 of the rigid portion A1.

The gate electrode 132 may overlap the semiconductor layer 122 and may be disposed to correspond to the central part of the semiconductor layer 122. Accordingly, the gate electrode 132 may also overlap the light blocking layer 112.

The signal pad 134 may be spaced apart from the semiconductor layer 122 and the light blocking layer 112.

In addition, a source pad 136 may be provided on the gate insulation layer 130 of the pad portion A3.

The gate electrode 132, the signal pad 134, and the source pad 136 may be formed of a conductive material such as metal. For example, the gate electrode 132, the signal pad 134, and the source pad 136 may be formed of at least one of aluminum (Al), copper (Cu), molybdenum (Mo), titanium (Ti), chromium (Cr), nickel (Ni), tungsten (W), or an alloy thereof. The gate electrode 132, the signal pad 134, and the source pad 136 may have a single-layered structure or a multiple-layered structure.

A first interlayer insulation layer 140 may be provided on the gate electrode 132 and the signal pad 134 of the rigid portion A1 as a fourth insulation layer. In the rigid portion Al, the first interlayer insulation layer 140 may cover and contact at least one side surfaces of the first buffer layer 110, the second buffer layer 120, and the gate insulation layer 130.

The first interlayer insulation layer 140 may be formed as a single layer or multiple layers of an inorganic insulating material. The inorganic insulating material of the first interlayer insulation layer 140 may include silicon nitride (SiNₓ), silicon oxide (SiOₓ), or silicon oxynitride (SiON).

In addition, the first interlayer insulation layer 140 may be provided in the soft portion A2 and the pad portion A3. In the soft portion A2, the first interlayer insulation layer 140 may be in contact with the first buffer layer 110. Alternatively, when the first buffer layer 110 is completely removed in the soft portion A2, the first interlayer insulation layer 140 may be in contact with the first adhesive layer 102.

Additionally, in the pad portion A3, the first interlayer insulation layer 140 may cover and contact at least one side surfaces of the first buffer layer 110, the second buffer layer 120, and the gate insulation layer 130.

An auxiliary electrode 142 may be provided on the first interlayer insulation layer 140 of the rigid portion A1. The auxiliary electrode 142 may overlap the light blocking layer 112 and may be in contact with the light blocking layer 112 through a contact hole provided in the second buffer layer 120, the gate insulation layer 130, and the first interlayer insulation layer 140. The auxiliary electrode 142 may be spaced apart from the semiconductor layer 122, the gate electrode 132, and the signal pad 134.

The auxiliary electrode 142 may be formed of a conductive material such as metal. For example, the auxiliary electrode 142 may be formed of at least one of aluminum (Al), copper (Cu), molybdenum (Mo), titanium (Ti), chromium (Cr), nickel (Ni), tungsten (W), or an alloy thereof. The auxiliary electrode 142 may have a single-layered structure or a multiple-layered structure.

A second interlayer insulation layer 150 may be provided on the auxiliary electrode 142 of the rigid portion A1 as a fifth insulation layer. The second interlayer insulation layer 150 may be formed as a single layer or multiple layers of an inorganic insulating material. The inorganic insulating material of the second interlayer insulation layer 150 may include silicon nitride (SiNₓ), silicon oxide (SiOₓ), or silicon oxynitride (SiON).

In addition, the second interlayer insulation layer 150 may be provided in the soft portion A2 and the pad portion A3. In the soft portion A2 and the pad portion A3, the second interlayer insulation layer 150 may be in contact with the first interlayer insulation layer 140.

A source electrode 152, a drain electrode 154, and a signal line 156 may be provided on the second interlayer insulation layer 150 of the rigid portion A1.

The source electrode 152 and the drain electrode 154 may be spaced apart from each other with the gate electrode 132 positioned therebetween and may be in contact with both ends of the semiconductor layer 122 through contact holes provided in the first and second interlayer insulation layers 140 and 150 and the gate insulation layer 130. In addition, the source electrode 152 may overlap the auxiliary electrode 142 and may be in contact with the auxiliary electrode 142 through a contact hole provided in the second interlayer insulation layer 150.

The semiconductor layer 122, the gate electrode 132, the source electrode 152, and the drain electrode 154 may constitute a thin film transistor TR.

The signal line 156 may be spaced apart from the thin film transistor TR and may overlap the signal pad 134. The signal line 156 may be in contact with the signal pad 134 through a contact hole provided in the first and second interlayer insulation layers 140 and 150.

A plurality of stretchable lines 158 may be provided on the second interlayer insulation layer 150 of the soft portion A2 and may be spaced apart from each other. The stretchable lines 158 may extend into and may also be provided in rigid portion A1 and the pad portion A3.

At least one stretchable line 158 may be directly connected to the drain electrode 154 and be configured as being one body with the drain electrode 154 in the rigid portion A1. However, embodiments of the present disclosure are not limited thereto. In other embodiments, the stretchable line 158 may be separated and spaced apart from the drain electrode 154.

Additionally, in the pad portion A3, the stretchable line 158 may overlap the source pad 136 and may be in contact with the source pad 136 through a contact hole provided in the first and second interlayer insulation layers 140 and 150. Here, the part of the stretchable line 158 contacting the source pad 136 may be the link line.

Meanwhile, in the soft portion A2, each of the first buffer layer 110, the first interlayer insulation layer 140, and the second interlayer insulation layer 150 disposed under the stretchable lines 158 may be patterned and separated to correspond to each stretchable line 158. In this case, the width of each stretchable line 158 may be smaller than the width of the first buffer layer 110, the first interlayer insulation layer 140, and the second interlayer insulation layer 150 corresponding thereto.

The source electrode 152, the drain electrode 154, the signal line 156, and the stretchable line 158 may be formed of a conductive material such as metal. For example, the source electrode 152, the drain electrode 154, the signal line 156, and the stretchable line 158 may be formed of at least one of aluminum (Al), copper (Cu), molybdenum (Mo), titanium (Ti), chromium (Cr), nickel (Ni), tungsten (W), or an alloy thereof. The source electrode 152, the drain electrode 154, the signal line 156, and the stretchable line 158 may have a single-layered structure or a multiple-layered structure.

A planarization layer 160 may be provided on the source electrode 152, the drain electrode 154, the signal line 156, and the stretchable line 158 of the rigid portion A1 as a sixth insulation layer. The planarization layer 160 may eliminate a step difference due to the layers thereunder and may have a substantially flat top surface. The planarization layer 160 may be formed of an organic insulating material such as photosensitive acrylic polymer (photo acryl).

In addition, the planarization layer 160 may be provided on the stretchable line 158 of the pad portion A3 and may not be provided in the soft portion A2. The planarization layer 160 may cover the parts of the stretchable line 158 of the rigid portion A1 and the pad portion A3 and may expose the part of the stretchable line 158 of the soft portion A2.

In the pad portion A3, the planarization layer 160 may expose one end of the stretchable line 158, and the planarization layer 160 may not overlap and may be spaced apart from the source pad 136.

A first contact electrode 162, a second contact electrode 164, and a reflection layer 166 may be provided on the planarization layer 160 of the rigid portion A1.

The first contact electrode 162 and the second contact electrode 164 may be formed of a conductive material such as metal. For example, the first contact electrode 162 and the second contact electrode 164 may be formed of at least one of aluminum (Al), copper (Cu), molybdenum (Mo), titanium (Ti), chromium (Cr), nickel (Ni), tungsten (W), or an alloy thereof. The first contact electrode 162 and the second contact electrode 164 may have a single-layered structure or a multiple-layered structure.

The first contact electrode 162 may overlap the drain electrode 154 and may be in contact with the drain electrode 154 through a contact hole provided in the planarization layer 160.

The second contact electrode 164 may overlap the signal line 156. In other embodiments, the second contact electrode 164 may be in contact with the signal line 156 through a contact hole provided in the planarization layer 160.

The reflection layer 166 may be disposed between the first and second contact electrodes 162 and 164 and may be formed of a material having relatively high reflectance. The reflection layer 166 may be formed of a different material from the first and second contact electrodes 162 and 164. Alternatively, the reflection layer 166 may be formed of the same material as the first and second contact electrodes 162 and 164. In other embodiments, the reflection layer 166 may be omitted.

Meanwhile, in the soft portion A2, the encapsulation layer 170 may be provided on the stretchable line 158 exposed and not covered by the planarization layer 160. The encapsulation layer 170 may have a substantially flat top surface.

In some areas of the rigid portion A1 and the pad portion A3, the encapsulation layer 170 may overlap the planarization layer 160 and may be in contact with the top and side surfaces of the planarization layer 160. The encapsulation layer 170 may be spaced apart from the first contact electrode 162, the second electrode 164, and the reflection layer 166 in the rigid portion A1 and may be spaced apart from the source pad 136 in the pad portion.

In the soft portion A2, the encapsulation layer 170 may be patterned and separated to correspond to each stretchable line 158 and may cover top and side surfaces of each stretchable line 158. Additionally, in the soft portion A2, the encapsulation layer 170 may cover and contact the side surfaces of the first buffer layer 110, the first interlayer insulation layer 140, and the second interlayer insulation layer 150 under each stretchable line 158 and may also be in contact with the top surface of the first adhesive layer 102 or the first substrate 101.

The encapsulation layer 170 may have an inclined side surface. That is, the side surface of the encapsulation layer 170 may have an inclination with a predetermined angle less than 90 degrees with respect to the first substrate 101. Accordingly, the width of the encapsulation layer 170 may decrease from the bottom side of the encapsulation layer 170 contacting the first adhesive layer 102 to the top side of the encapsulation layer 170 far from the first adhesive layer 102, and the width of the top side of the encapsulation layer 170 may be smaller than the width of the bottom side of the encapsulation layer 170. Here, the width of the top side of the encapsulation layer 170 may be greater than the width of the stretchable line 158.

In addition, a distance from the first substrate 101 to the top surface of the encapsulation layer 170 may be greater than a distance from the first substrate 101 to the top surfaces of the first and second contact electrodes 162 and 164. That is, the distance from the first substrate 101 to the top surface of the encapsulation layer 170 may be greater than a distance from the first substrate 101 to the top surface of the planarization layer 160.

Accordingly, the maximum thickness of the encapsulation layer 170 may be greater than a sum of thicknesses of the insulation layers provided in the rigid portion Al, i.e., the first buffer layer 110, the second buffer layer 120, the gate insulation layer 130, the first interlayer insulation layer 140, the second interlayer insulation layer 150, and the planarization layer 160. For example, the thickness of the encapsulation layer 170 may be 6 um or less, and in one embodiment is 3 um to 5 um.

The encapsulation layer 170 may be formed of an insulating material and may be formed of a rigid material having lower flexibility than the soft material of the first substrate 101. For example, the encapsulation layer 170 may be formed of a polyimide (PI) resin or epoxy resin.

The encapsulation layer 170 may have relatively high elastic modulus, and the elastic modulus of the encapsulation layer 170 may be higher than the elastic modulus of the first substrate 101. For example, the elastic modulus of the encapsulation layer 170 may be more than 1,000 times higher than the elastic modulus of the first substrate 101, but embodiments of the present disclosure are not limited thereto.

Next, in the rigid portion A1, an adhesive layer 172 may be provided on the first contact electrode 162, the second contact electrode 164, and the reflection layer 166. The adhesive layer 172 may be in contact with the top surface of the planarization layer 160. The adhesive layer 172 may be provided substantially all over the rigid portion A1.

The adhesive layer 172 may have a substantially flat top surface and may be formed of an organic insulating material such as photosensitive acrylic polymer (photo acryl).

The adhesive layer 172 may extend into the soft portion A2 and the pad portion A3 and may be provided on the encapsulation layer 170. In addition, the adhesive layer 172 may be in contact with the side surface of the encapsulation layer 170 in the rigid portion A1 and may expose the side surfaces of the planarization layer 160 and the encapsulation layer 170 in the pad portion A3.

In the pad portion A3, the edge of the adhesive layer 172 may protrude beyond the edge of the encapsulation layer 170, and thus may protrude from the side surface of the encapsulation layer 170 toward the edge of the first substrate 101, so that the bottom surface of the adhesive layer 172 may be partially exposed. Further, in the pad portion A3, the adhesive layer 172 may expose the end of the stretchable line 158, and the adhesive layer 172 may not overlap and may be spaced apart from the source pad 136.

Meanwhile, in the soft portion A2, the adhesive layer 172 may be patterned and separated to correspond to each stretchable line 158. The width of the adhesive layer 172 may be greater than the width of the top side of the encapsulation layer 170 corresponding thereto, so that an undercut structure in which the bottom surface of the adhesive layer 172 is exposed may be formed.

However, embodiments of the present disclosure are not limited thereto, and in other embodiments, the adhesive layer 172 may be removed in the soft portion A2 and the pad portion A3.

A light-emitting element 180 may be provided on the adhesive layer 172. The light-emitting element 180 may overlap the reflection layer 166 and may be disposed between the first contact electrode 162 and the second contact electrode 164. Here, it is preferable that the width and area of the reflection layer 166 is equal to or greater than the width and area of the light-emitting element 180.

The light-emitting element 180 may include a first electrode 180a and a second electrode 180b. Here, the first electrode 180a may be a p-electrode, and the second electrode 180b may be an n-electrode. The first electrode 180a may be an anode, and the second electrode 180b may be a cathode. However, embodiments of the present disclosure are not limited thereto.

Alternatively, in other embodiments, the first electrode 180a may be an n-electrode, and the second electrode 180b may be a p-electrode. In this case, the first electrode 180a may be a cathode, and the second electrode 180b may be an anode.

The light-emitting element 180 may be provided in the form of a micro light-emitting diode chip (micro-LED chip or uLED chip) including the n-electrode, an n-type layer, an active layer, a p-type layer, and the p-electrode. The light-emitting element 180 may have a lateral structure in which the n-electrode and the p-electrode are provided on the same side (e.g., a side facing the second substrate 106) and light is emitted through the same side provided with the n-electrode and the p-electrode (e.g., the side facing the second substrate 106). Accordingly, the first electrode 180a and the second electrode 180b may be provided on the side facing the second substrate 106.

However, embodiments of the present disclosure are not limited thereto. The light-emitting element 180 may have a flip-chip structure in which the n-electrode and the p-electrode are provided on the same side (e.g., a side facing the first substrate 101) and light is emitted through a side opposite to the side provided with the n-electrode and the p-electrode (e.g., a side facing the second substrate 106) or may have a vertical structure in which the n-electrode and the p-electrode are provided on opposite sides, respectively. In this case, the adhesive layer 172 may include conductive balls inside.

A first connection electrode 182 and a second connection electrode 184 may be provided on the light-emitting element 180. The first connection electrode 182 may be in contact with the first electrode 180a, and the second connection electrode 184 may be in contact with the second electrode 180b. In addition, the first connection electrode 182 may be in contact with the first contact electrode 162 through a contact hole provided in the adhesive layer 172, and the second connection electrode 184 may be in contact with the second contact electrode 164 through a contact hole provided in the adhesive layer 172. Accordingly, the first electrode 180a of the light-emitting element 180 may be electrically connected to the first contact electrode 162 through the first connection electrode 182, and the second electrode 180b of the light-emitting element 180 may be electrically connected to the second contact electrode 164 through the second connection electrode 184.

A protection layer 188 may be provided on the light-emitting element 180 and the first and second connection electrodes 182 and 184. The protection layer 188 may be provided substantially all over the rigid portion A1 to thereby cover and protect the light-emitting element 180 and the first and second connection electrodes 182 and 184 and may be in contact with the top surface of the adhesive layer 172.

The protection layer 188 may extend into the soft portion A2 and the pad portion A3 and may also be provided on the adhesive layer 172.

In the pad portion A3, the edge of the protection layer 188 may protrude from the edge of the adhesive layer 172 toward the edge of the first substrate 101, so that the bottom surface of the protection layer 188 may be partially exposed. The protection layer 188 may expose the side surfaces of the adhesive layer 172, the encapsulation layer 170, and the planarization layer 160 in the pad portion A3. Further, in the pad portion A3, the protection layer 188 may expose the end of the stretchable line 158, and the protection layer 188 may not overlap and may be spaced apart from the source pad 136.

Meanwhile, in the soft portion A2, the protection layer 188 may be patterned and separated to correspond to each stretchable line 158. The width of the protection layer 188 may be greater than the width of the adhesive layer 172 corresponding thereto, so that an undercut structure in which the bottom surface of the protection layer 188 is exposed may be formed. The protection layer 188 may be used as a hard mask for etching the adhesive layer 172 and the encapsulation layer 170 thereunder, and this will be described later.

The protection layer 188 may be formed as a single layer or multiple layers of an inorganic insulating material. The inorganic insulating material of the protection layer 188 may include silicon nitride (SiNₓ), silicon oxide (SiOₓ), or silicon oxynitride (SiON).

Meanwhile, the flexible printed circuit 192 may be attached onto the stretchable line 158 of the pad portion A3. The flexible printed circuit 192 may be electrically connected to the source pad 136 through the stretchable line 158.

A second adhesive layer 108 may be provided on the protection layer 188 and the flexible printed circuit 192, and the second substrate 106 may be disposed on the second adhesive layer 108.

The second adhesive layer 108 may attach the first substrate 101 provided with the light-emitting element 180 and the stretchable lines 158 with the second substrate 106.

In the soft portion A2, the second adhesive layer 108 may be in contact with the side surfaces of the encapsulation layer 170, the adhesive layer 172, and the protection layer 188. The second adhesive layer 108 may be disposed between adjacent patterns of the encapsulation layer 170 and be in contact with the first adhesive layer 102 in the soft portion A2.

In the pad portion A3, the second adhesive layer 108 may be in contact with the side surfaces of the planarization layer 160, the encapsulation layer 170, the adhesive layer 172, and the protection layer 188 and also be in contact with the stretchable lines 158.

The second adhesive layer 108 may be formed of the same material as the first adhesive layer 102. The second adhesive layer 108 may have substantially the same thickness as the first adhesive layer 102.

As such, in the stretchable display device according to the first embodiment of the present disclosure, the first buffer layer 110, the first interlayer insulation layer 140, and the second interlayer insulation layer 150 may be provided to be patterned under each stretchable line 158, thereby protecting and supporting the stretchable line 158, and the encapsulation layer 170 may be provided over each stretchable line 158, thereby protecting and supporting the stretchable line 158. Accordingly, since the stretchable line 158 is surrounded by the second interlayer insulation layer 150 and the encapsulation layer 170 and is not exposed, the electrical short circuit between the light-emitting element 180 and the stretchable line 158 may be prevented during transfer of light-emitting element 180.

In addition, the step difference between the rigid portion A1 and the soft portion A2 may be minimized or at least reduced due to the encapsulation layer 170, thereby substantially flattening the rigid portion A1 and the soft portion A2, so that various light-emitting elements 180 of the lateral structure, the flip-chip structure, or the vertical structure can be applied.

Further, as compared with the related art stretchable display device provided with the base substrate between the first adhesive layer and the first buffer layer, in the stretchable display device according to the first embodiment of the present disclosure, the base substrate may be omitted, so that the thickness of the display device can be decreased, and the stretching properties can be improved.

Meanwhile, the encapsulation layer 170 of the soft portion A2 may be selectively removed through a dry etch process using the protection layer 188 as a hard mask, and the encapsulation layer 170 may be over-etched in some areas to be etched over the entire display area DA.

In this case, the side surface of the encapsulation layer 170 may be inclined due to the anisotropic properties of the dry etch, so that the width of the top side of the encapsulation layer 170 may be smaller than the width of the bottom side of the encapsulation layer 170.

Here, in order to prevent or at least reduce the stretchable line 158 from being exposed, the final unilateral margin may be required which is a distance between an edge of the stretchable line 158 and an edge of the encapsulation layer 170 corresponding thereto, and the width of the encapsulation layer 170 may be decided by the width of the stretchable line 158 and the final unilateral margin.

However, in the stretchable display device according to the first embodiment of the present disclosure, since the stretchable line 158 is disposed on the bottom side of the encapsulation layer 170 having the wider width than the top side thereof, the final unilateral margin may be designed based on the width of the bottom side of the encapsulation layer 170 or the width of the stretchable line 158.

On the other hand, in the related art stretchable display device, since the base substrate is provided under the stretchable line, the final unilateral margin may be designed based on the top side of the base substrate having the narrower width than the bottom side thereof.

Accordingly, for the same final unilateral margin, the widths of the top and bottom sides of the encapsulation layer 170 of the present disclosure may be smaller than the widths of the top and bottom sides of the base substrate of the related art, so that the stretching properties can be improved.

In addition, since the area corresponding to the stretchable line 158 decreases, an additional area for designing the lines may be secured, thereby improving the stretching reliability.

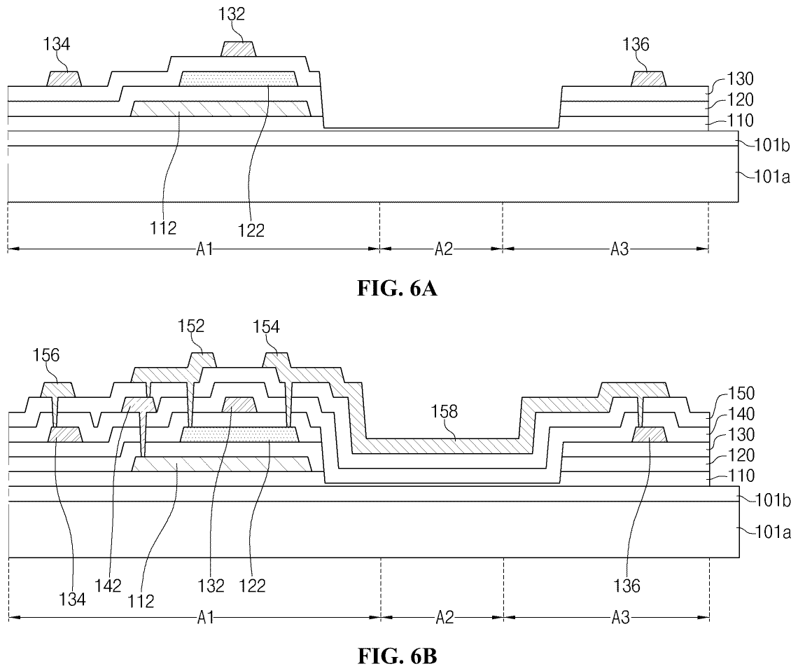

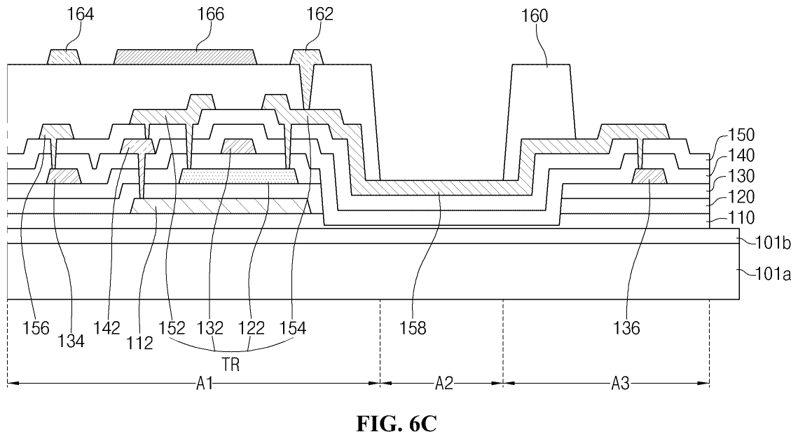

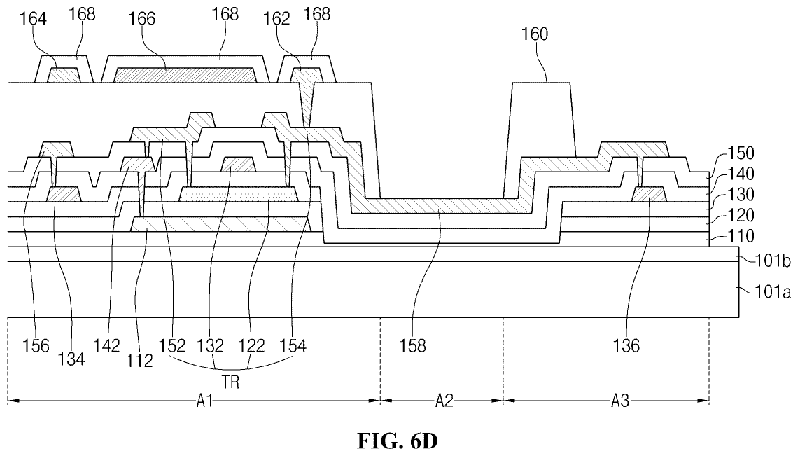

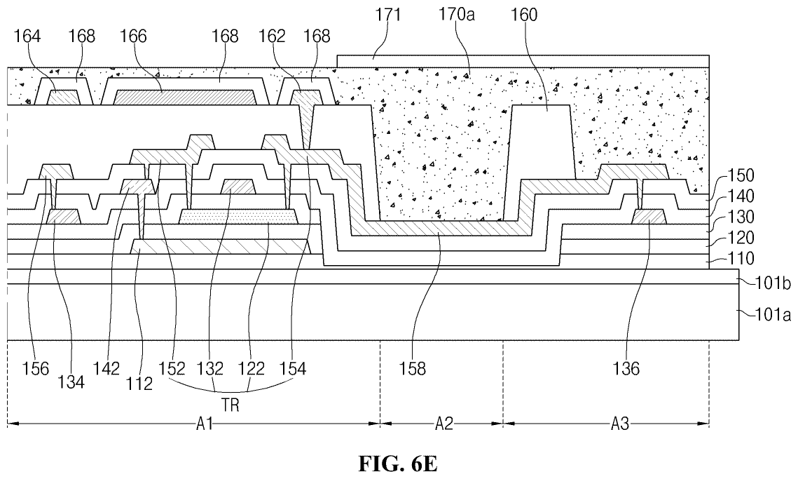

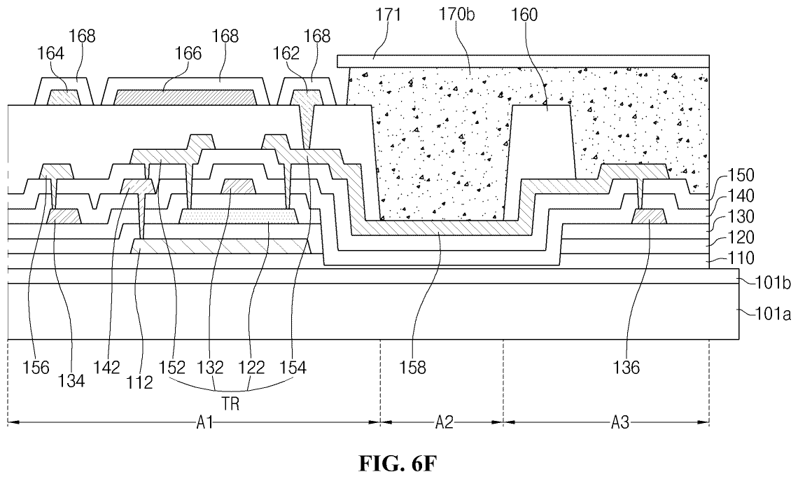

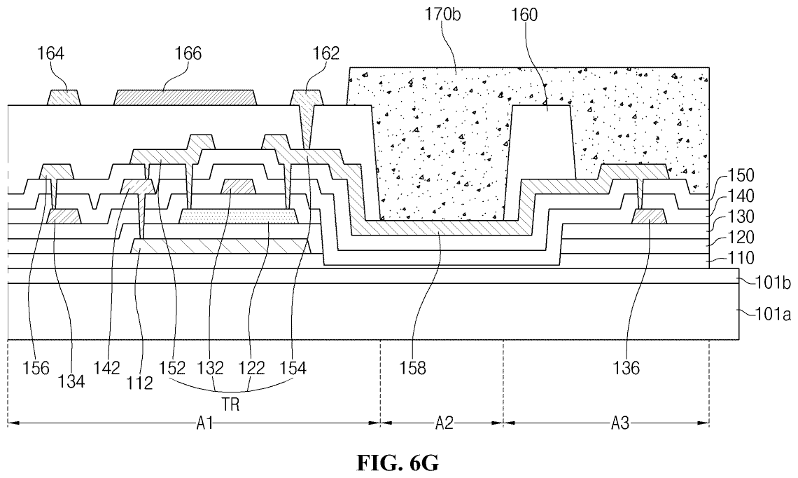

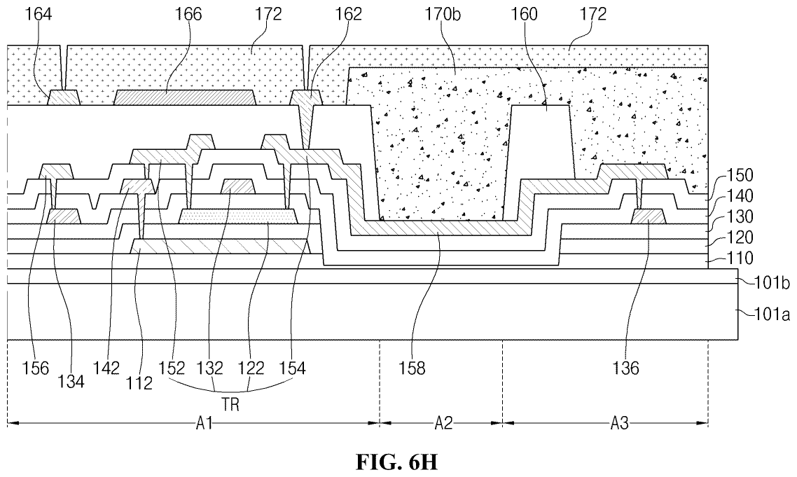

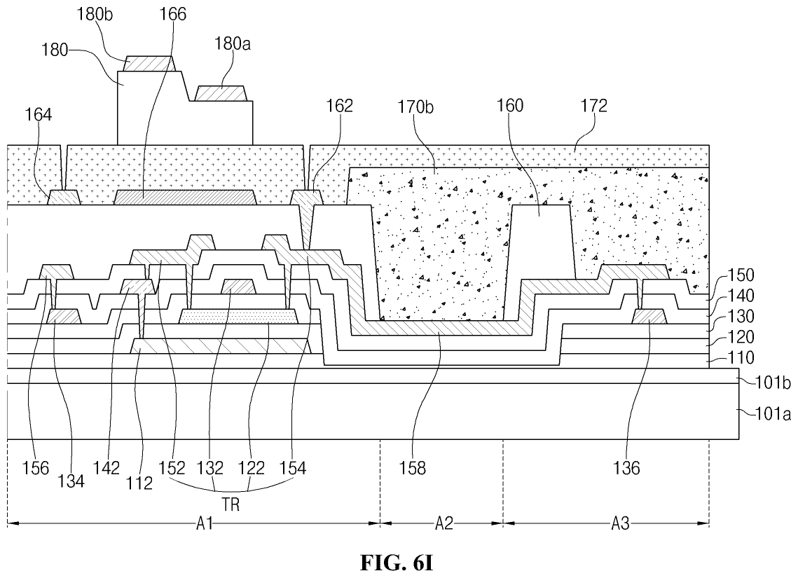

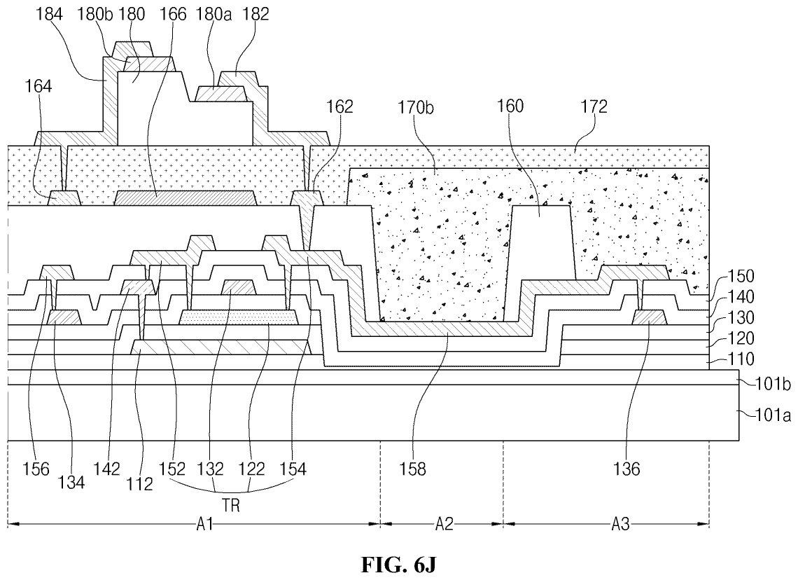

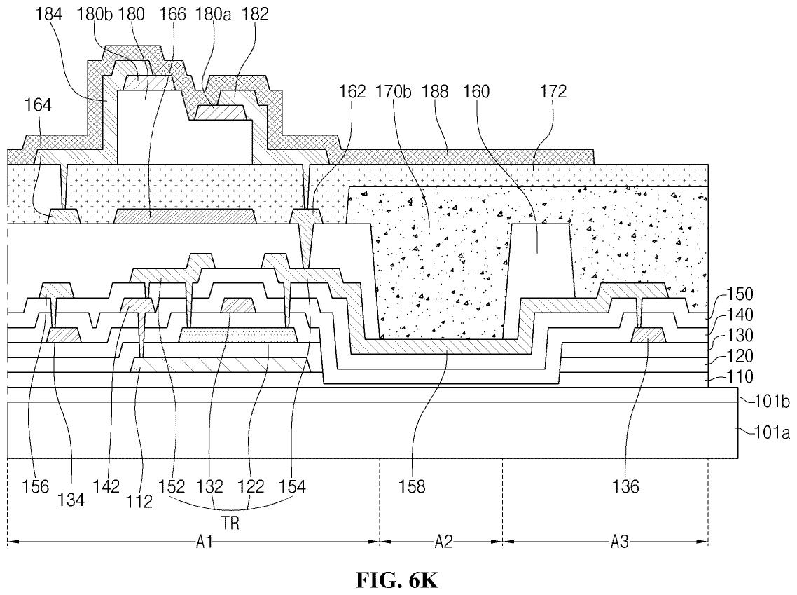

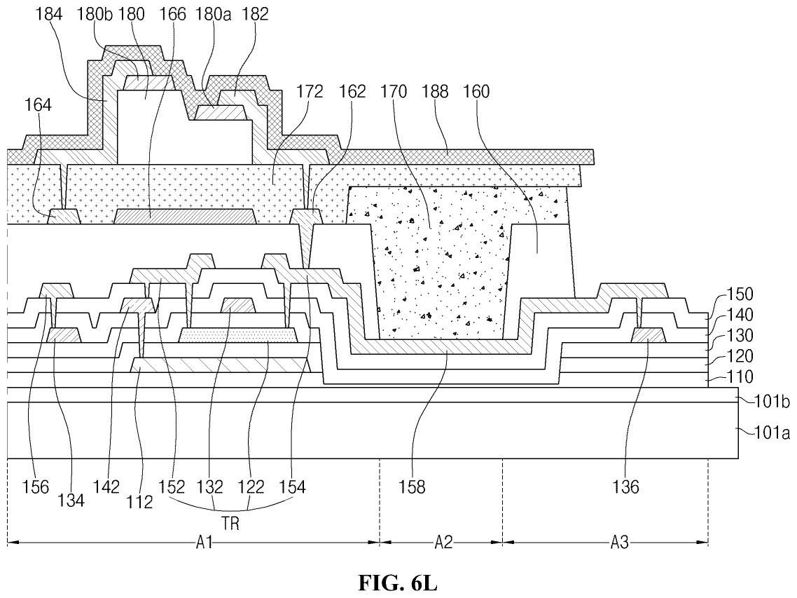

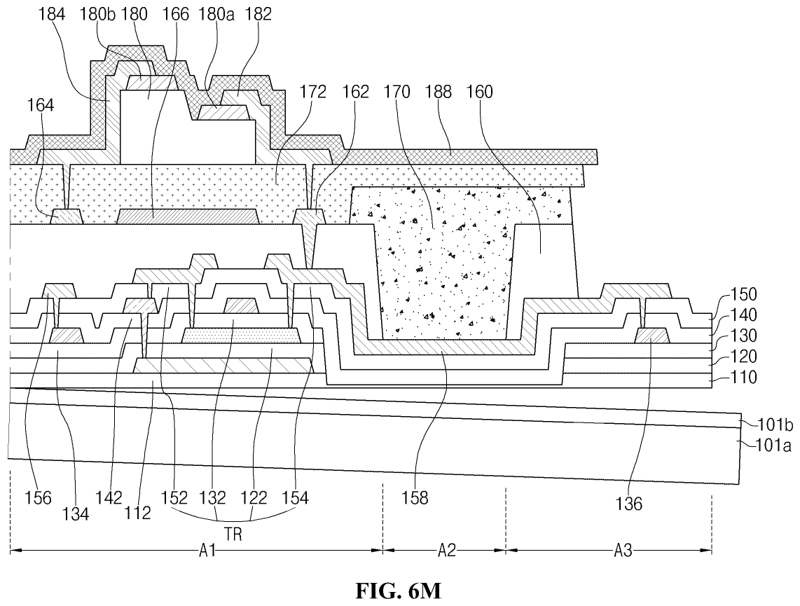

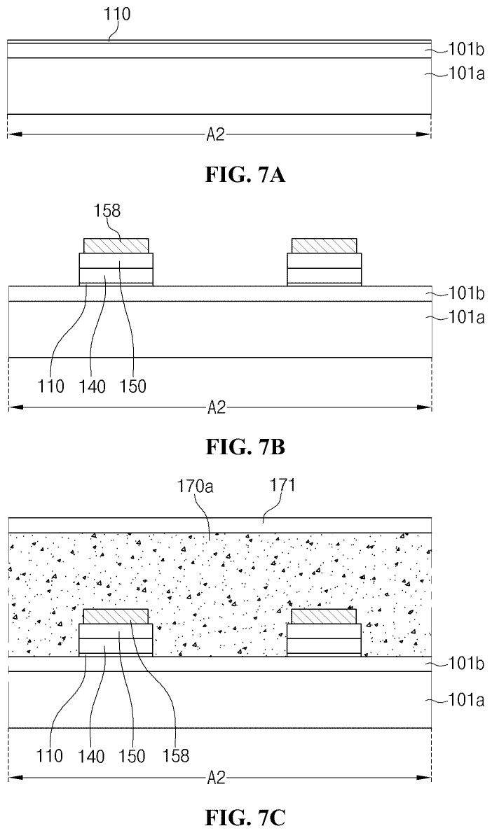

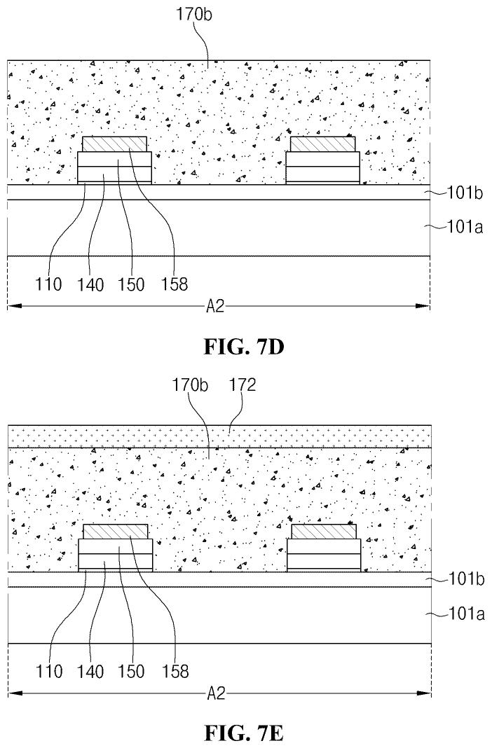

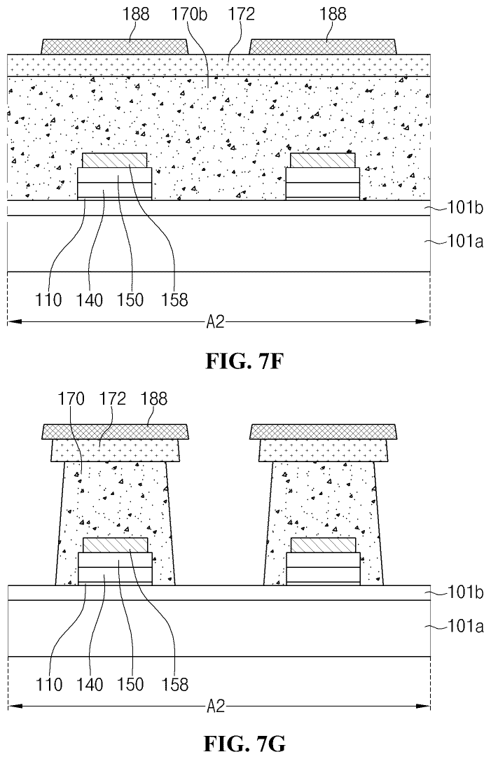

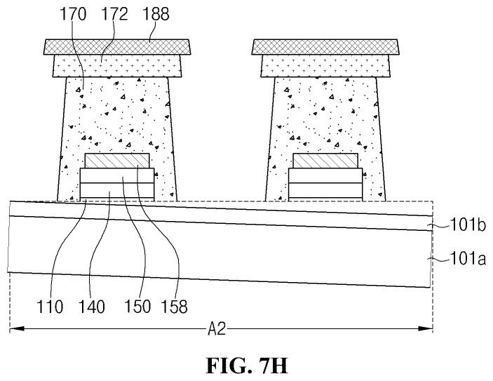

A method of manufacturing a stretchable display device according to the first embodiment of the present disclosure will be described with reference to FIGS. 6A to 6M and FIGS. 7A to 7H.

FIGS. 6A to 6M are schematic cross-sectional views of a stretchable display device corresponding to line I-I′ of FIG. 2 in steps of manufacturing the same according to the first embodiment of the present disclosure. FIGS. 7A to 7H are schematic cross-sectional views of a stretchable display device corresponding to line II-II′ of FIG. 2 in steps of manufacturing the same according to the first embodiment of the present disclosure. FIGS. 6A to 6M and FIGS. 7A to 7H will be described with reference to FIG. 4 and FIG. 5 together.

In FIG. 6A and FIG. 7A, a sacrificial layer 101b may be formed on a carrier substrate 101a provided with the rigid portion A1, the soft portion A2, and the pad portion A3. Here, the sacrificial layer 101b may be an inorganic layer and may be formed through a deposition process. For example, the sacrificial layer 101b may be formed by stacking amorphous silicon (a-Si) and silicon nitride (SiNₓ). In addition, the carrier substrate 101a may be formed of glass.

Then, the first buffer layer 110 may be formed on the sacrificial layer 101b by depositing an inorganic insulating material over substantially the entire surface of the carrier substrate 101a, and the light shielding layer 112 may be formed in the rigid portion A1 by depositing a conductive material on the first buffer layer 110 and then patterning it through a photolithography process.

Next, the second buffer layer 120 may be formed on the light shield layer 112 and the first buffer layer 110 by depositing an inorganic insulating material over substantially the entire surface of the carrier substrate 101a, and the semiconductor layer 122 may be formed in the rigid portion A1 by depositing a semiconductor material on the second buffer layer 120 and then patterning it through a photolithography process. The semiconductor layer 122 may overlap the light shielding layer 112.

Next, the gate insulation layer 130 may be formed on the semiconductor layer 122 and the second buffer layer 120 by depositing an inorganic insulating material over substantially the entire surface of the carrier substrate 101a, and the gate insulation layer 130, the second buffer layer 120, and the first buffer layer 110 may be selectively removed in the soft portion A2 through a photolithography process. In this case, the first buffer layer 110 may be completely removed and may partially remain in the soft portion A2.

Meanwhile, the gate insulation layer 130, the second buffer layer 120, and the first buffer layer 110 may also partially removed in the rigid portion A1 and pad portion A3.

Then, the gate electrode 132 and the signal pad 134 may be formed in the rigid portion A1 and the source pad 136 may be formed in the pad portion A3 by depositing a conductive material on the gate insulation layer 130 and then patterning it through a photolithography process.

Next, in FIG. 6B and FIG. 7B, the first interlayer insulation layer 140 may be formed on the gate electrode 132, the signal pad 134, the source pad 136, and the gate insulation layer 130 by depositing an inorganic insulating material over substantially the entire surface of the carrier substrate 101a, and the contact hole exposing the light shielding layer 112 may be formed by selectively removing the first interlayer insulation layer 140, the gate insulation layer 130, and the second buffer layer 120 through a photolithography process. The first interlayer insulation layer 140 may be in contact with the side surfaces of the first buffer layer 110, the second buffer layer 120, and the gate insulation layer 130 in the rigid portion A1 and the pad portion A3 and the top surface of the first buffer layer 110 in the soft portion A2.

Then, the auxiliary electrode 142 may be formed in the rigid portion A1 by depositing a conductive material on the first interlayer insulation layer 140 and then patterning it through a photolithography process. The auxiliary electrode 142 may be in contact with the light shielding layer 112 through the contact hole provided in the second buffer layer 120, the gate insulation layer 130, and the first interlayer insulation layer 140.

Next, the second interlayer insulation layer 150 may be formed on the auxiliary electrode 142 and the first interlayer insulation layer 140 by depositing an inorganic insulating material over substantially the entire surface of the carrier substrate 101a, and the contact holes exposing the semiconductor layer 122, the signal pad 134, the source pad 136, and the auxiliary electrode 152 may be formed by selectively removing the second interlayer insulation layer 150, the first interlayer insulation layer 140, and/or the gate insulation layer 130 through a photolithography process in the rigid portion A1 and the pad portion A3.

Additionally, in the soft portion A2, the second interlayer insulation layer 150, the first interlayer insulation layer 140, and the gate insulation layer 130 may be selectively removed and separated into the plurality of patterns spaced apart from each other.

Next, the source electrode 152, the drain electrode 154, and the signal line 156 may be formed in the rigid portion A1 and the stretchable line 158 may be formed in the soft portion A2 by depositing a conductive material on the second interlayer insulation layer 150 and then patterning it through a photolithography process.

The source electrode 152 and the drain electrode 154 may be in contact with the semiconductor layer 122 through the contact holes provided in the gate insulation layer 130 and the first and second interlayer insulation layers 140 and 150. The signal line 156 may be in contact with the signal pad 134 through the contact hole formed in the first and second interlayer insulation layer 140 and 150. In addition, the source electrode 152 may be in contact with the auxiliary electrode 122 through the contact hole formed in the second interlayer insulation layer 150.

In the soft portion A2, the stretchable line 158 may have the narrower width than the first buffer layer 110, the first interlayer insulation layer 140, and the second interlayer insulation layer 150 that are patterned.

Meanwhile, the stretchable line 158 may extend into the rigid portion A1 and may be connected to the drain electrode 154. The stretchable line 158 may also extend into the pad portion A3 and may be in contact with the source pad 136 through the contact hole formed in the first interlayer insulation layer 140 and the second interlayer insulation layer 150.

Next, in FIG. 6C, the planarization layer 160 may be formed on the source electrode 152, the drain electrode 154, the signal line 156, the stretchable line 158, and the second interlayer insulation layer 150 by applying an organic insulating material over substantially the entire surface of the carrier substrate 101a and then may be patterned through a photolithography process to thereby expose the stretchable line 158 in the soft portion A2. That is, the planarization layer 160 may be provided only in the rigid portion A1 and the pad portion A3 and may not be provided in the soft portion A2. In addition, the planarization layer 160 may expose one end of the stretchable line 158 overlapping the source pad 136 in the pad portion A3.

At this time, the contact hole exposing the drain electrode 154 may also be formed in the planarization layer 160 of the rigid portion A1.

Then, the first contact electrode 162, the second contact electrode 164, and the reflection layer 166 may be formed in the rigid portion A1 by depositing a conductive material on the planarization layer 160 and then patterning it through a photolithography process.

In other embodiments, the first and second contact electrodes 162 and 164 and the reflection layer 166 may be formed of different materials through different photolithography processes.

Next, in FIG. 6D, a first mask pattern 168 may be formed to cover each of the first contact electrode 162, the second contact electrode 164, and the reflection layer 166 by depositing a conductive material or an inorganic insulating material on the first and second contact electrodes 162 and 164, the reflection layer 166, the planarization layer 160, and the stretchable line 158 and then patterning it through a photolithography process.

The first mask pattern 168 may be formed of a transparent conductive oxide. For example, first mask pattern 168 may be formed of indium tin oxide (ITO) or indium zinc oxide (IZO).

Next, in FIG. 6E and FIG. 7C, a first encapsulation material layer 170a may be formed on the first mask pattern 168, the planarization layer 160, and the stretchable line 158 by applying an insulating material over substantially the entire surface of the carrier substrate 101a. For example, the first encapsulation material layer 170a may be formed of a polyimide (PI) resin or epoxy resin.

Then, a second mask pattern 171 may be formed in the soft portion A2 and the pad portion A3 by depositing a conductive material or an inorganic insulating material on the first encapsulation material layer 170a and then patterning it through a photolithography process. The second mask pattern 171 may expose the top surface of the first encapsulation material layer 170a in the rigid portion A1.

The second mask pattern 171 may be formed of the same material as the first mask pattern 168. For example, the second mask pattern 171 may be formed of a transparent conductive oxide such as indium tin oxide (ITO) or indium zinc oxide (IZO).

Next, in FIG. 6F, the first encapsulation material layer 170a exposed in the rigid portion A1 may be removed using the second mask pattern 171 as a hard mask, thereby forming a second encapsulation material layer 170b under the second mask pattern 171 and exposing the first mask pattern 168 on the first and second contact electrodes 162 and 164 and the reflection layer 166.

Here, the first encapsulation material layer 170a may be removed through a dry etch process. The first encapsulation material layer 170a may be over-etched, so that an undercut structure in which the bottom surface of the second mask pattern 171 is exposed may be formed.

Next, in FIG. 6G and 7D, the first and second mask patterns 168 and 171 may be removed, thereby exposing the first and second contact electrodes 162 and 164, the reflection layer 166, and the second encapsulation material layer 170b.

Here, the first and second mask patterns 168 and 171 may be removed through a wet etch process.

Next, in FIG. 6H and 7E, the adhesive layer 172 may be formed on the first and second contact electrodes 162 and 164, the reflection layer 166, and the second encapsulation material layer 170b by applying an organic insulating material over substantially the entire surface of the carrier substrate 101a and first curing it. Then, the adhesive layer 172 may be selectively removed through a photolithography process to thereby form the contact holes exposing the first and second contact electrodes 162 and 164.

Here, the adhesive layer 172 may not be completely cured and may have viscosity. For example, the adhesive layer 172 may be formed of photosensitive acrylic polymer (photo acryl).

Next, in FIG. 6I, the light-emitting element 180 may be transferred on the adhesive layer 172 corresponding to the reflection layer 166, and the light-emitting element 180 may be fixed to the adhesive layer 172 by secondly curing the adhesive layer 172. In this case, the adhesive layer 172 may be completely cured by applying UV or heat.

The light-emitting element 180 may have the bottom surface attached to the adhesive layer 172 and the top surface on which the first and second electrodes 180a and 180b are provided. The light-emitting element 180 may overlap the reflection layer 166 and may be spaced apart from the contact holes of the adhesive layer 172.

Next, in FIG. 6J, the first connection electrode 182 and the second connection electrode 184 may be formed in the rigid portion A1 by depositing a conductive material on the light-emitting element 180 and the adhesive layer 172 and then patterning it through a photolithography process. The first connection electrode 182 may be in contact with the first electrode 180a and the first contact electrode 162, and the second connection electrode 184 may be in contact with the second electrode 180b and the second contact electrode 164.

Next, in FIG. 6K and FIG. 7F, the protection layer 188 may be formed on the light-emitting element 180, the first and second connection electrodes 182 and 184, and the adhesive layer 172 by depositing an inorganic insulating material over substantially the entire surface of the carrier substrate 101a and then patterning it through a photolithography process.

The protection layer 188 may be provided substantially all over the rigid portion A1 to thereby cover and protect the light-emitting element 180 and the first and second connection electrodes 182 and 184. The protection layer 188 may expose the top surface of the adhesive layer 172 in the soft portion A2 and the pad portion A3.

Specifically, in the soft portion A2, the protection layer 188 may be patterned to overlap each stretchable line 158 and expose the top surface of the adhesive layer 172 between adjacent stretchable lines 158. Additionally, in the pad portion A3, the protection layer 188 may expose the top surface of the adhesive layer 172 on the source pad 136.

In FIG. 6L and FIG. 7G, by selectively removing the adhesive layer 172 exposed in the soft portion A2 and the pad portion A3 using the protection layer 188 as a hard mask, and then by selectively removing the second encapsulation material layer 170b under the adhesive layer 172, the encapsulation layer 170 may be formed and be separated to correspond to each stretchable line 158 in the soft portion A2. At this time, the end of the stretchable line 1158 may be exposed in the pad portion A3.

Here, the adhesive layer 172 and the second encapsulation material layer 170b may be removed through a dry etch process, and the side surfaces of the adhesive layer 172 and the encapsulation layer 170 may have the inclination with respect to the carrier substrate 101a. The width of the top side of each of the adhesive layer 172 and the encapsulation layer 170 may be smaller than the width of the bottom side of each of the adhesive layer 172 and the encapsulation layer 170.

In addition, the adhesive layer 172 and the second encapsulation material layer 170b may be over-etched, thereby forming the undercut structure in which the bottom surfaces of the protection layer 188 and the adhesive layer 172 are exposed. Accordingly, the widths of the top and bottom sides of the adhesive layer 172 may be greater than the width of the top side of the encapsulation layer 170 and smaller than the width of the protection layer 188.

Next, in FIG. 6M and FIG. 7H, the carrier substrate 101a and the sacrificial layer 101b may be separated from the first buffer layer 110 and the encapsulation layer 170. In this case, by irradiating a laser beam from the bottom of the carrier substrate 101a, the carrier substrate 101a and the sacrificial layer 101b may be separated.

Next, in FIG. 4 and FIG. 5, the first adhesive layer 102 and the first substrate 101 may be attached to the bottom surfaces of the first buffer layer 110 and the encapsulation layer 170, and the second adhesive layer 108 and the second substrate 106 may be attached to the top surface of the protection layer 188, thereby completing the display panel of the stretchable display device.

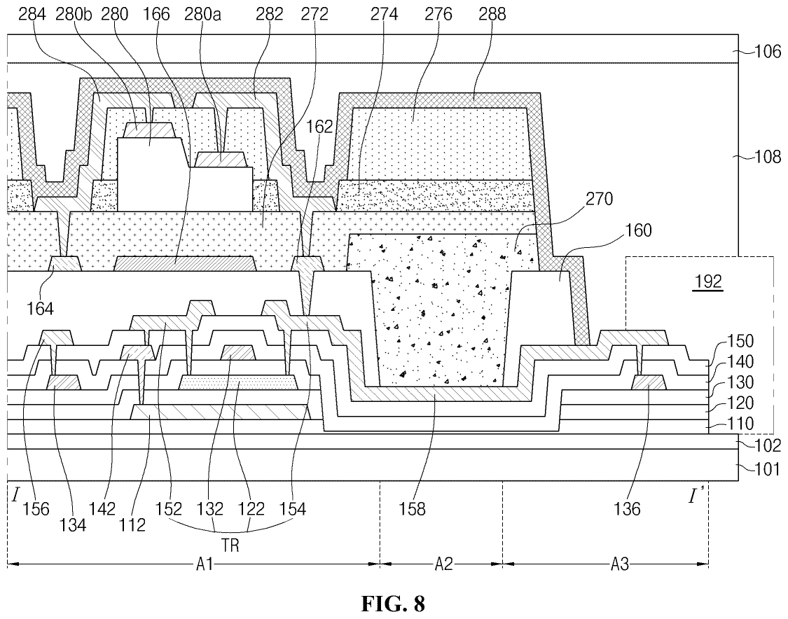

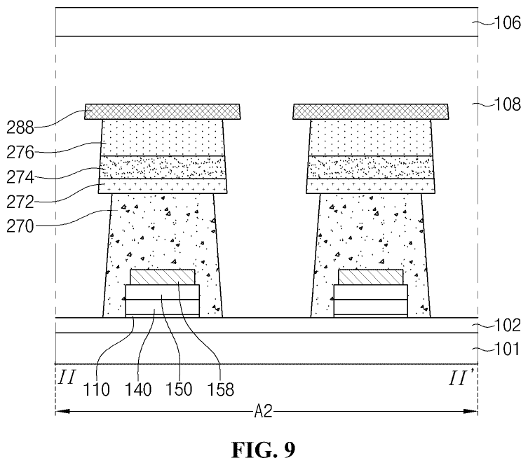

FIG. 8 and FIG. 9 are cross-sectional views corresponding to one sub-pixel of a stretchable display device according to a second embodiment of the present disclosure. FIG. 8 shows a cross-section corresponding to line I-I′ of FIG. 2, and FIG. 9 shows a cross-section corresponding to line II-II′ of FIG. 2. The stretchable display device according to the second embodiment of the present disclosure has substantially the same configuration as that of the first embodiment, except for the protection layer. The same parts as those of the first embodiment are designated by the same or similar reference signs, and explanation for the same parts may be shortened or omitted.

In FIG. 8 and FIG. 9, the stretchable display device according to the second embodiment of the present disclosure may include the first substrate 101 provided with the rigid portion Al, the soft portion A2, and the pad portion A3. The thin film transistor TR and the stretchable line 158 may be formed on the first substrate 101, and the planarization layer 160 may be formed on the thin film transistor TR and the stretchable line 158. The planarization layer 160 may expose the stretchable line 158 in the soft portion A2.

The first contact electrode 162, the second contact electrode 164, and the reflection layer 166 may be formed on the planarization layer 160 of the rigid portion A1, and the encapsulation layer 270 may be formed on the stretchable line 158 in the soft portion A2. The encapsulation layer 270 may be patterned and separated to correspond to each stretchable line 158 and may cover the top and side surfaces of each stretchable line 158.

In addition, the first buffer layer 110, the first interlayer insulation layer 140, and the second interlayer insulation layer 150 may be formed under the stretchable line 158. The encapsulation layer 270 may cover and contact the side surfaces of the first buffer layer 110, the first interlayer insulation layer 140, and the second interlayer insulation layer 150 and may be in contact with the top surface of the first adhesive layer 102.

Next, the adhesive layer 272 may be formed on the first and second contact electrodes 162 and 164, the reflection layer 166, and the encapsulation layer 270. The adhesive layer 272 may be provided substantially all over the rigid portion A1. In the rigid portion A1, the adhesive layer 272 may have the contact holes exposing the first and second contact electrodes 162 and 164.

Additionally, in the soft portion A2, the adhesive layer 272 may be patterned and separated to correspond to each stretchable line 158. The width of the adhesive layer 272 may be greater than the width of the top side of the encapsulation layer 270 corresponding thereto, so that an undercut structure in which the bottom surface of the adhesive layer 272 is exposed may be formed.

The light-emitting element 280 may be provided on the adhesive layer 272. The light-emitting element 280 may overlap the reflection layer 166 and may be disposed between the first contact electrode 162 and the second contact electrode 164. The first electrode 280a and the second electrode 280b of the light-emitting element 280 may be provided on the side facing the second substrate 106.

In addition, a first protection layer 274 and a second protection layer 276 may be provided on the adhesive layer 272. The first protection layer 274 and the second protection layer 276 may have substantially flat top surfaces. The first protection layer 274 and the second protection layer 276 may be provided substantially all over the rigid portion A1.

In the soft portion A2, the first protection layer 274 and the second protection layer 276 may be patterned and separated to correspond to each stretchable line 158. In this case, the first protection layer 274 and the second protection layer 276 may have the inclined side surfaces together with the adhesive layer 272. The widths of the adhesive layer 272, the first protection layer 274, and the second protection layer 276 may decrease from the adhesive layer 272 to the second protection layer 276.

The first protection layer 274 and the second protection layer 276 may be formed of the same organic insulating material. For example, the first protection layer 274 and the second protection layer 276 may be formed of photosensitive acrylic polymer (photo acryl). However, embodiments of the present disclosure are not limited thereto. In other embodiments, the first protection layer 274 and the second protection layer 276 may be formed of different organic insulating materials.

Here, the total thickness of the first protection layer 274 and the second protection layer 276 may be greater than the thickness of the light-emitting element 280. In this case, the thickness of the first protection layer 274 may be smaller than the thickness of the light-emitting element 280. Accordingly, the first protection layer 274 may not cover the light-emitting element 280 and may be in contact with the side surfaces of the light-emitting element 280. On the other hand, the second protection layer 276 may cover the light-emitting element 280 and may be in contact with the top and side surfaces of the light-emitting element 280.

The first and second protection layers 274 and 276 may have contact holes exposing the first contact electrode 162 and the second contact electrode 164, and the second protection layer 276 may have contact holes exposing the first electrode 280a and the second electrode 280b.

However, embodiments of the present disclosure are not limited thereto. In other embodiments, the first protection layer 274 and the second protection layer 276 may be provided as one layer having the thicker thickness than the light-emitting element 280. For example, the first protection layer 274 may be omitted, and the thickness of the second protection layer 276 may be greater than that of the light-emitting element 280.

Next, the first connection electrode 282 and the second connection electrode 284 may be formed on the second protection layer 276. The first connection electrode 282 may be in contact with the first electrode 280a through the contact hole formed in the second protection layer 276 and be in contact with the first contact electrode 162 through the contact hole provided in the first and second protection layers 274 and 276 and the contact hole provided in the adhesive layer 272. In addition, the second connection electrode 284 may be in contact with the second electrode 280b through the contact hole formed in the second protection layer 276 and be in contact with the second contact electrode 164 through the contact hole provided in the first and second protection layers 274 and 276 and the contact hole provided in the adhesive layer 272.

A third protection layer 288 may be provided on the first and second connection electrodes 282 and 284 and the second protection layer 276. The third protection layer 288 may be provided substantially all over the rigid portion A1 to thereby cover and protect the first and second connection electrodes 282 and 284, the first protection layer 274, and the second protection layer 276. In addition, the third protection layer 288 may cover and be in contact with the side surfaces of the planarization layer 160, the encapsulation layer 270, the adhesive layer 272, the first protection layer 274, and the second protection layer 276 in the pad portion A3.

Meanwhile, in the soft portion A2, the third protection layer 288 may be patterned and separated to correspond to each stretchable line 158. The width of the third protection layer 288 may be greater than the width of the second protection layer 276 corresponding thereto, so that an undercut structure in which the bottom surface of the third protection layer 288 is exposed may be formed. The third protection layer 288 may be used as a hard mask for etching the first and second protection layers 274 and 276, the adhesive layer 272, and the encapsulation layer 270 thereunder.

The flexible printed circuit 192 may be attached onto the stretchable line 158 of the pad portion A3. The second adhesive layer may be provided on the third protection layer 288 and the flexible printed circuit 192, and the second substrate 106 may be disposed on the second adhesive layer 108.

As such, in the stretchable display device according to the second embodiment of the present disclosure, the first protection layer 274 and/or the second protection layer 276 of an organic insulating material may be provided on the light-emitting element 280, thereby protecting the light-emitting element 280 and facilitating formation of the first and second connection electrodes 282 and 284.

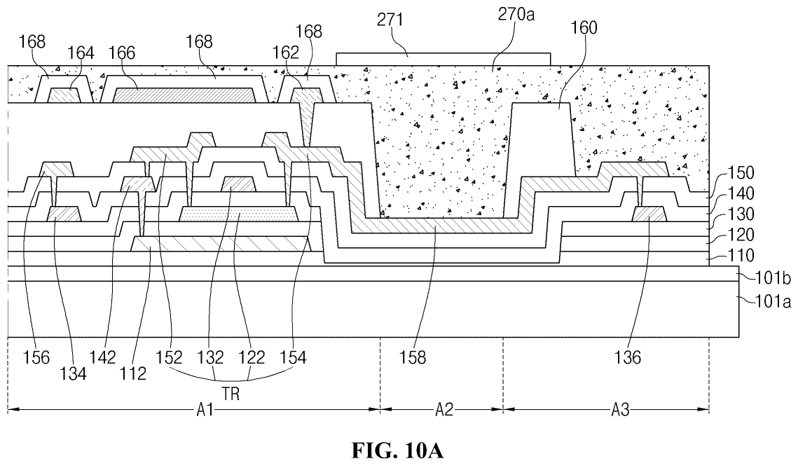

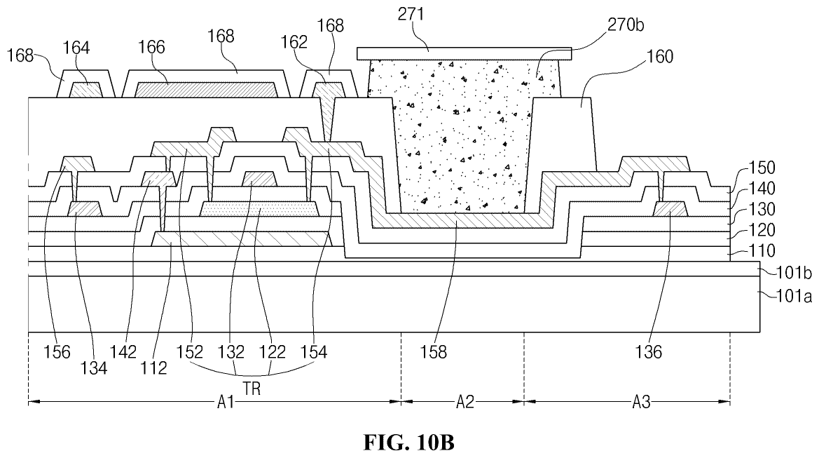

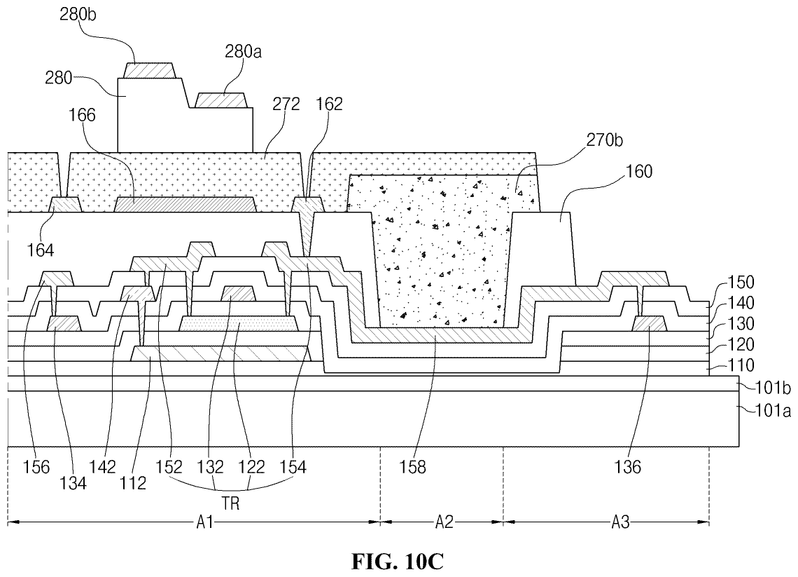

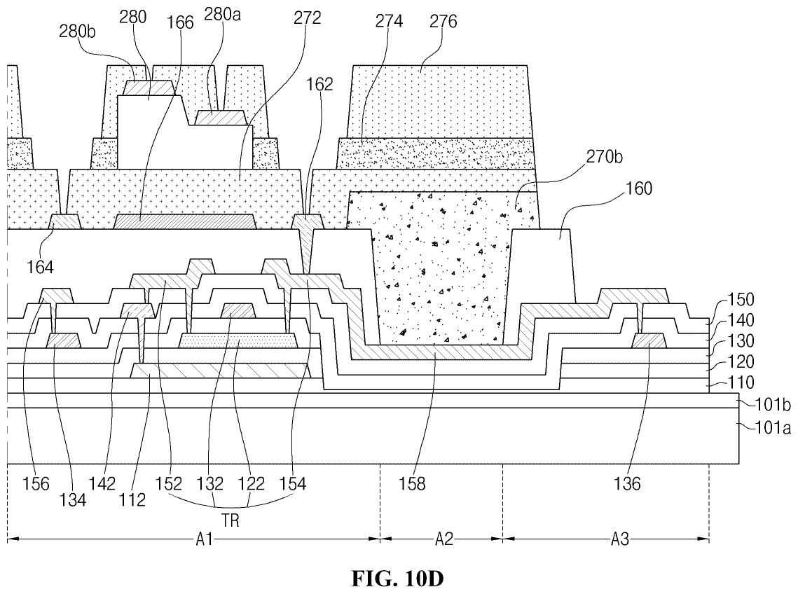

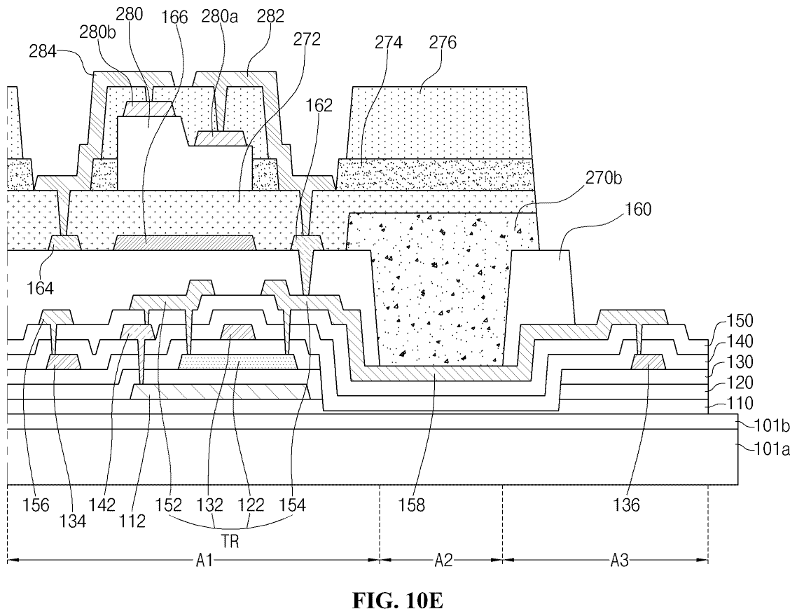

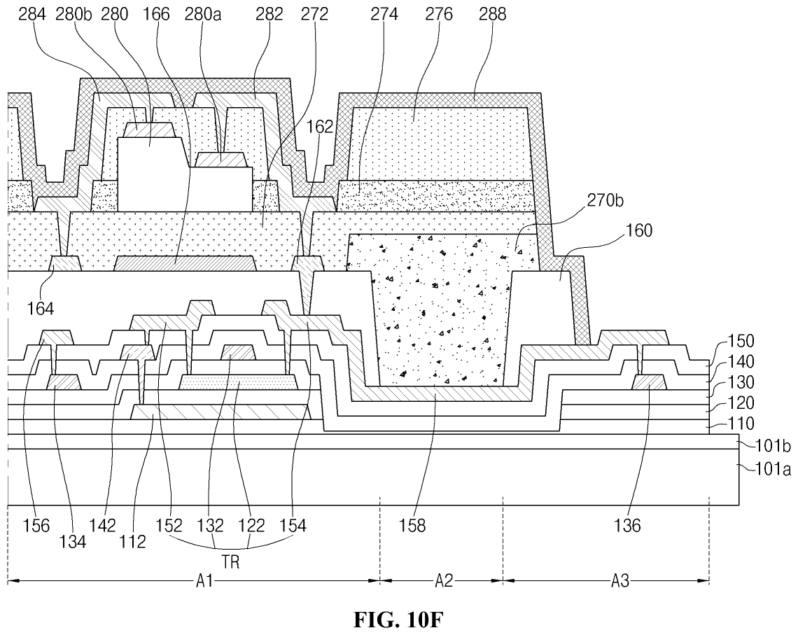

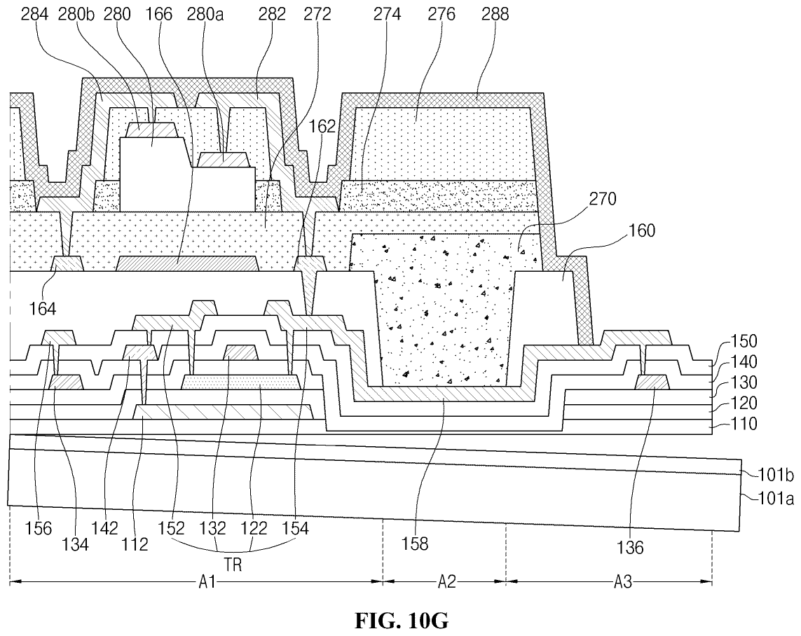

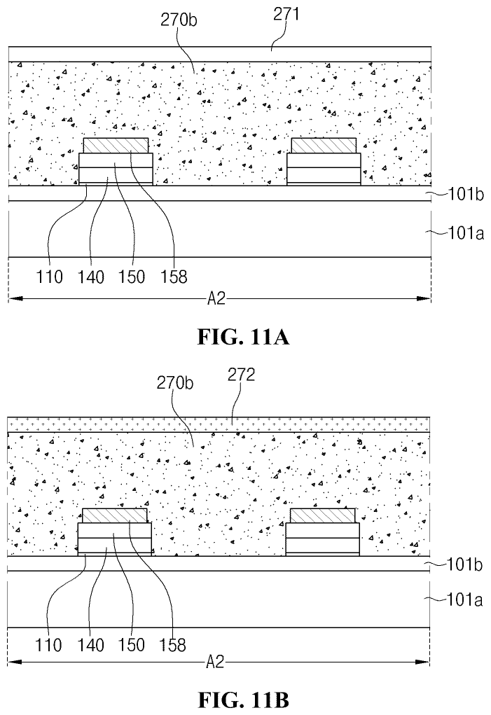

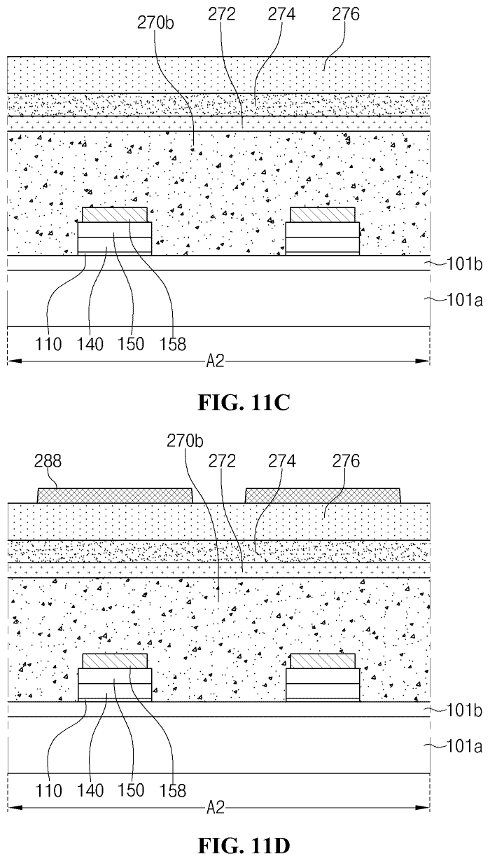

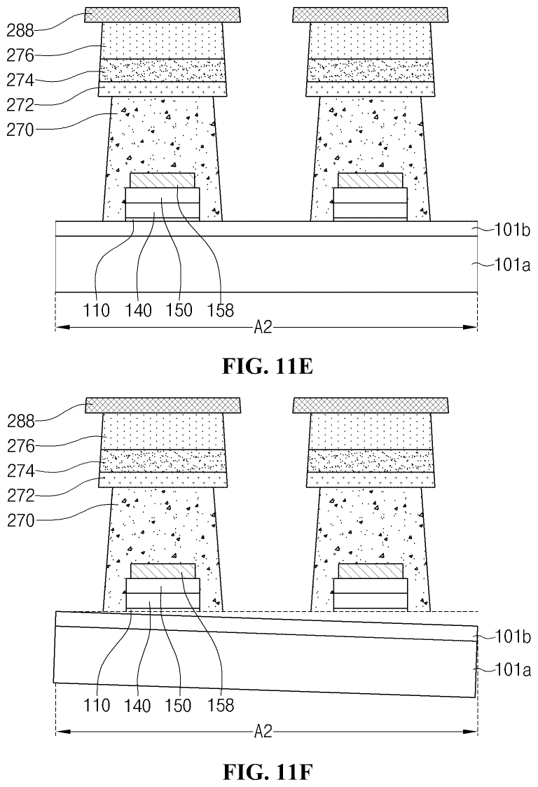

A method of manufacturing a stretchable display device according to the second embodiment of the present disclosure will be described with reference to FIGS. 10A to 10G and FIGS. 11A to 11F.

FIGS. 10A to 10G are schematic cross-sectional views of a stretchable display device corresponding to line I-I′ of FIG. 2. FIGS. 11A to 11F in steps of manufacturing the same according to the second embodiment of the present disclosure and show cross-sections. FIGS. 10A to 10G and FIGS. 11A to 11F will be described with reference to FIG. 8 and FIG. 9 together.

Meanwhile, in the stretchable display device according to the second embodiment of the present disclosure, components up to the first mask pattern 168 may be formed on the carrier substrate 101a through the same steps of FIGS. 6A to 6D and FIGS. 7A and 7B, and the description thereof will be omitted.

In FIG. 10A and FIG. 11A, a first encapsulation material layer 270a may be formed on the first mask pattern 168, the planarization layer 160, and the stretchable line 158 by applying an insulating material over substantially the entire surface of the carrier substrate 101a. For example, the first encapsulation material layer 270a may be formed of a polyimide (PI) resin or epoxy resin.

Then, a second mask pattern 271 may be formed in the soft portion A2 by depositing a conductive material or an inorganic insulating material on the first encapsulation material layer 270a and then patterning it through a photolithography process. The second mask pattern 271 may be partially formed in the rigid portion A1 and the pad portion A3 may expose the top surface of the first encapsulation material layer 270a in the rigid portion A1 and the pad portion A3.

The second mask pattern 271 may be formed of the same material as the first mask pattern 168. For example, the second mask pattern 271 may be formed of a transparent conductive oxide such as indium tin oxide (ITO) or indium zinc oxide (IZO).

Next, in FIG. 10B, the first encapsulation material layer 270a exposed in the rigid portion A1 and the pad portion A3 may be removed using the second mask pattern 271 as a hard mask, thereby forming a second encapsulation material layer 270b under the second mask pattern 271 and exposing the first mask pattern 168 on the first and second contact electrodes 162 and 164 and the reflection layer 166. In this case, one end of the stretchable line 158 and the planarization layer 160 may also be exposed in the pad portion A3.

Here, the first encapsulation material layer 270a may be removed through a dry etch process. The first encapsulation material layer 270a may be over-etched, so that an undercut structure in which the bottom surface of the second mask pattern 271 is exposed may be formed.

Then, the first and second mask patterns 168 and 271 may be removed, thereby exposing the first and second contact electrodes 162 and 164, the reflection layer 166, and the second encapsulation material layer 270b.

Next, in FIG. 10C and 11B, the adhesive layer 272 may be formed on the first and second contact electrodes 162 and 164, the reflection layer 166, and the second encapsulation material layer 270b by applying an organic insulating material over substantially the entire surface of the carrier substrate 101a and first curing it. Then, the adhesive layer 272 may be selectively removed through a photolithography process to thereby form the contact holes exposing the first and second contact electrodes 162 and 164. In this case, the adhesive layer 272 may also be removed in the pad portion A3 and may not be removed and remain in the soft portion A2.

Here, the adhesive layer 272 may not be completely cured and may have viscosity. For example, the adhesive layer 272 may be formed of photosensitive acrylic polymer (photo acryl).

Then, the light-emitting element 280 may be transferred on the adhesive layer 272 corresponding to the reflection layer 166, and the light-emitting element 280 may be fixed to the adhesive layer 272 by secondly curing the adhesive layer 272. In this case, the adhesive layer 272 may be completely cured by applying UV or heat.

Next, in FIG. 10D and FIG. 11C, the first protection layer 274 and the second protection layer 276 having the plurality of contact holes may be formed on the light-emitting element 280 and the adhesive layer 272 by applying and curing a first organic insulating material, applying and curing a second organic insulating material, and the selectively removing them through a photolithography process. In this case, the first protection layer 274 and the second protection layer 276 may also be removed in the pad portion A3 and may not be removed and remain in the soft portion A2.

Here, the first organic insulating material and the second organic insulating material may be the same material.

The first protection layer 274 and the second protection layer 276 may have the contact holes exposing the first contact electrode 162 and the second contact electrode 164, and the second protection layer 276 may have the contact holes exposing the first electrode 280a and the second electrode 280b.

Next, in FIG. 10E, the first connection electrode 282 and the second connection electrode 284 may be formed in the rigid portion A1 by depositing a conductive material on the second protection layer 276 and then patterning it through a photolithography process. The first connection electrode 282 may be in contact with the first electrode 280a and the first contact electrode 162, and the second connection electrode 284 may be in contact with the second electrode 280b and the second contact electrode 164.

Next, in FIG. 10F and FIG. 11D, the third protection layer 288 may be formed on the first and second connection electrodes 282 and 284 and the second protection layer 276 by depositing an inorganic insulating material over substantially the entire surface of the carrier substrate 101a and then patterning it through a photolithography process.

The third protection layer 288 may be provided substantially all over the rigid portion Al to thereby cover and protect the light-emitting element 280 and the first and second connection electrodes 282 and 284. In the pad portion A3, the third protection layer 288 may be in contact with the side surfaces of the planarization layer 160, the second encapsulation layer 270b, the adhesive layer 272, the first protection layer 274, and the second protection layer 276 and may expose the stretchable line 158 on the source pad 136.

Meanwhile, in the soft portion A2, the third protection layer 288 may be patterned to overlap each stretchable line 158 and expose the top surface of the second protection layer 276 between adjacent stretchable lines 158.

In FIG. 11E, by selectively removing the second protection layer 276 exposed in the soft portion A2 and the first protection layer 274 and the adhesive layer 272 thereunder using the third protection layer 288 mask as a hard mask, and then by selectively removing the second encapsulation material layer 270b under the adhesive layer 272, the encapsulation layer 270 may be formed and be separated to correspond to each stretchable line 158 in the soft portion A2.

Here, the first and second protection layers 274 and 276, the adhesive layer 272, and the second encapsulation material layer 270b may be removed through a dry etch process, and the side surfaces of the first and second protection layers 274 and 276, the adhesive layer 272, and the encapsulation layer 270 may have the inclination with respect to the carrier substrate 101a. The width of the top side of each of the first and second protection layers 274 and 276, the adhesive layer 272, and the encapsulation layer 270 may be smaller than the width of the bottom side of each of the first and second protection layers 274 and 276, the adhesive layer 272, and the encapsulation layer 270.

In addition, the first and second protection layers 274 and 276, the adhesive layer 272, and the second encapsulation material layer 270b may be over-etched, thereby forming the undercut structure in which the bottom surfaces of the third protection layer 288 and the adhesive layer 272 are exposed.

Next, in FIG. 10G and FIG. 11F, the carrier substrate 101a and the sacrificial layer 101b may be separated from the first buffer layer 110 and the encapsulation layer 270. In this case, by irradiating a laser beam from the bottom of the carrier substrate 101a, the carrier substrate 101a and the sacrificial layer 101b may be separated.

Next, in FIG. 8 and FIG. 9, the first adhesive layer 102 and the first substrate 101 may be attached to the bottom surfaces of the first buffer layer 110 and the encapsulation layer 270, and the second adhesive layer 108 and the second substrate 106 may be attached to the top surface of the third protection layer 288, thereby completing the display panel of the stretchable display device.

In the second embodiment of the present disclosure, the third protection layer 288 may be in contact with the side surfaces of the planarization layer 160, the encapsulation layer 270, the adhesive layer 272, the first protection layer 274, and the second protection layer 276 in the pad portion A3, but embodiments of the present disclosure are not limited thereto. In other embodiments, similarly to the protection layer 188 of the first embodiment, the third protection layer 288 may expose the side surfaces of the planarization layer 160, the encapsulation layer 270, the adhesive layer 272, the first protection layer 274, and the second protection layer 276 in the pad portion A3.

Alternatively, similarly to the third protection layer 288 of the second embodiment, the protection layer 188 of the first embodiment may be in contact with the side surfaces of the first planarization layer 160, the encapsulation layer 170, and the adhesive layer 172 in the pad portion A3.

That is, the manufacturing method of the first embodiment and the manufacturing method of the second embodiment may be applied to each other.

In the stretchable display device of the present disclosure, by providing the encapsulation layer on the stretchable line, the step difference between the rigid portion and the soft portion may be minimized or at least reduced, so that various structures of the light-emitting element can be applied, and the electrical short circuit can be prevented during transfer of light-emitting element.

In addition, the base substrate under the stretchable can be omitted, and thus the thickness of the display device can be reduced, thereby improving the stretching properties.

Further, since the width and area corresponding to the stretchable line is decreased, so that the stretching properties can be further improved, and the stretching reliability can be improved. Accordingly, by improving the lifetime, the production power consumption can be reduced to achieve the low power consumption.

It will be apparent to those skilled in the art that various modifications and variations can be made in the display device of the present disclosure without departing from the technical idea or scope of the disclosure. Thus, it is intended that the present disclosure cover the modifications and variations of this disclosure.

What is claimed is:

1. A stretchable display device, comprising:
a first substrate including a rigid portion and a soft portion;
a thin film transistor in the rigid portion on the first substrate;
a planarization layer on the thin film transistor;
a stretchable line in the soft portion on the first substrate;
an encapsulation layer on the stretchable line;
a light-emitting element on the planarization layer, the light-emitting element electrically connected to the thin film transistor; and
a second substrate spaced apart from the first substrate,
wherein a distance between the first substrate and a top surface of the encapsulation layer is greater than a distance between the first substrate and a top surface of the planarization layer.

2. The stretchable display device of claim 1, wherein the encapsulation layer is in contact with a top surface and a side surface of the stretchable line in the soft portion.

3. The stretchable display device of claim 1, further comprising:
a protection layer on the light-emitting element and the encapsulation layer.

4. The stretchable display device of claim 3, wherein a width of the protection layer is greater than a width of a top side of the encapsulation layer.

5. The stretchable display device of claim 3, further comprising:
an organic protection layer between the light-emitting element and the protection layer.

6. The stretchable display device of claim 3, further comprising:
a first contact electrode and a second contact electrode between the planarization layer and the light-emitting element; and
a first connection electrode and a second connection electrode between the light-emitting element and the protection layer,
wherein the first connection electrode is in contact with a first electrode of the light-emitting element and the first contact electrode, and the second connection electrode is in contact with a second electrode of the light-emitting element and the second contact electrode.

7. The stretchable display device of claim 1, further comprising:
a plurality of insulation layers between the first substrate and the planarization layer in the rigid portion and between the first substrate and the stretchable line in the soft portion,
wherein a thickness of the plurality of insulation layers between the first substrate and the planarization layer in the rigid portion is greater than a thickness of the plurality of insulation layers between the first substrate and the stretchable line in the soft portion.

8. The stretchable display device of claim 7, wherein the plurality of insulation layers between the first substrate and the planarization layer in the rigid portion includes a first insulation layer, a second insulation layer, a third insulation layer, a fourth insulation layer, and a fifth insulation layer, and
wherein the first insulation layer, the fourth insulation layer, and the fifth insulation layer are provided between the first substrate and the stretchable line in the soft portion and the second insulation layer and the third insulation layer are not provided between the first substrate and the stretchable line in the soft portion.

9. A method of manufacturing a stretchable display device, comprising:
forming a thin film transistor in a rigid portion on a substrate that is provided with the rigid portion and a soft portion;
forming a stretchable line in the soft portion on the substrate;
forming a planarization layer on the thin film transistor;
transferring a light-emitting element on the planarization layer, the light-emitting element electrically connected to the thin film transistor; and
forming an encapsulation layer on the stretchable line,
wherein a distance between the substrate and a top surface of the encapsulation layer is greater than a distance between the substrate and a top surface of the planarization layer.

10. The method of claim 9, further comprising:
forming a protection layer on the light-emitting element and the encapsulation layer.

11. The method of claim 10, wherein forming the encapsulation layer includes:
forming a first encapsulation material layer on the planarization layer and the stretchable line;
forming a second encapsulation material layer in the soft portion by selectively removing the first encapsulation material layer; and
selectively removing the second encapsulation material layer using the protection layer as a hard mask.

12. The method of claim 11, wherein a width of the protection layer is greater than a width of a top side of the encapsulation layer.

13. The method of claim 10, further comprising:
forming an organic protection layer between the light-emitting element and the protection layer.

14. The method of claim 10, further comprising:
forming a plurality of insulation layers between the substrate and the planarization layer in the rigid portion and between the substrate and the stretchable line in the soft portion,
wherein a thickness of the plurality of insulation layers between the substrate and the planarization layer in the rigid portion is greater than a thickness of the plurality of insulation layers between the substrate and the stretchable line in the soft portion.
